(19) United States
(12) Patent Application Publication
(10) Pub. No.: US 2022/0173340 A1
(43) Pub. Date: Jun. 2, 2022

(54) ORGANIC SINGLE-CRYSTALLINE HETEROJUNCTION COMPOSITE FILM, PREPARATION METHOD THEREOF AND METHOD OF USING THE SAME

(71) Applicant: ZHEJIANG UNIVERSITY, Hangzhou (CN)

(72) Inventors: Hanying Li, Hangzhou (CN); Ruihan Wu, Hangzhou (CN)

(21) Appl. No.: 17/533,156

(22) Filed: Nov. 23, 2021

Related U.S. Application Data
(63) Continuation of application No. PCT/CN2020/134142, filed on Dec. 5, 2020.

(30) Foreign Application Priority Data
Dec. 5, 2019 (CN) 201911237342.4

(51) Int. Cl. H01L 51/42; H01L 51/05; C30B 29/68; C30B 29/54; C30B 29/60; H01L 51/00

(52) U.S. Cl. CPC H01L 51/424; H01L 51/0583; H01L 51/0001; C30B 29/54; C30B 29/605; C30B 29/68

(57) ABSTRACT

An organic single-crystalline heterojunction composite film is provided. The organic single-crystalline heterojunction composite film comprises at least one organic single-crystalline efficiently coupled unit. The organic single-crystalline efficiently coupled unit constructed by two organic single-crystalline thin films laminated together, with highly efficient lamination. The organic single-crystalline heterojunction composite film of the present disclosure has multiple advantages, such as highly ordered molecular arrangement, few defects, long exciton diffusion length, and excellent charge carrier transportation in the single-crystalline layer, moreover, integration of optoelectronic function and flexibility could be realized. The preparation method of organic single-crystalline heterojunction composite film is also provided. High-quality organic single-crystalline heterojunction composite film has a wide range of applications in the fields of sensors, photodetectors, solar cells, displays, memory devices, complementary circuits, and so on.

### CROSS REFERENCE OF RELATED APPLICATIONS

This application is a continuation of PCT Patent Application No. PCT/CN2020/134142, filed on Dec. 5, 2020, entitled “ORGANIC SINGLE-CRYSTALLINE HETEROJUNCTION COMPOSITE FILM, PREPARATION METHOD THEREOF AND METHOD OF USING THE SAME,” which claims foreign priority of Chinese Patent Application No. 201911237342.4, filed Dec. 5, 2019 in the China National Intellectual Property Administration (CNIPA), the entire contents of which are hereby incorporated by reference in their entireties.

### TECHNICAL FIELD

The disclosure relates to the technical field of organic semiconductors, and particularly relates to an organic single-crystalline heterojunction composite film, preparation method thereof and method of using the same.

### BACKGROUND

Organic heterojunction is a junction composed of two or more different organic materials. By integrating different components into an active layer, multiple of electronic and optoelectronic functions can be realized in a synergistic way, and even extra novel functions. The organic heterojunction act as the most critical functional part in semiconductor devices, such as organic field-effect transistors (OFETs), organic solar cells (OSCs), organic light-emitting diodes (OLEDs), and memory devices. Organic heterojunctions also have an important impact on the performance improvement of optoelectronic devices and further applications. At the contact interface between two different materials in the organic heterojunction, the heterointerface is formed and plays a key part in optoelectronic devices. For OSCs, the donor-acceptor heterojunction in the active layer is composed of donors and acceptors (the active layer refers to the layer that plays a key function in the organic heterojunction), and the heterointerface between the donor and the acceptor is mainly used for the separation of illumination-generated excitons (exciton dissociation). The excitons need to transfer to the heterointerface within its lifetime after being separated into holes and electrons. Finally, the transportation of electrons and holes is displayed in the acceptor and donor materials until they are collected by the electrodes, respectively. The exciton diffusion length and carrier transportation greatly affect the power conversion efficiency of solar cell devices. Therefore, the composition and molecular ordering of the heterojunction take very important role in the quality and performance of the heterojunction. Currently, organic semiconductor materials can be divided into amorphous form and crystalline form according to the degree of ordering in their structure. Furthermore, the crystalline form could be divided into single-crystalline form and polycrystalline form. Most of the organic semiconductor materials are amorphous or polycrystalline in the active layer, leading to many shortcomings for the organic heterojunction. In the planar heterojunction (obtained by stacking amorphous donor and acceptor together) and the bulk heterojunction, the donor and acceptor form a three-dimensional interpenetrating network, however the problem of short exciton diffusion length cannot be directly overcome due to the low degree of molecular ordering. (H. Li et al., Angewandte Chemie International Edition, 54, 956 (2015)). Although the degree of ordering has been improved in the polycrystalline heterojunction, the random orientation and numerous grain boundaries not only hinder the exploration of the intrinsic physical properties of the related electronic devices, but also greatly reduce the performance of charge carrier transportation at the heterointerface.

Organic single-crystalline thin film is composed of organic single crystals. For organic semiconductor devices, the organic single-crystalline thin film is the most ideal material for active layer. Specifically, the organic single-crystalline thin film constituted by organic single crystals has multiple merits, such as fewer intrinsic defects, no grain boundaries, and long-range ordering in the molecular arrangement. The excellent performance in the field of optoelectronics has been shown, especially the high mobility in the devices. At present, the electron and hole mobility of field-effect transistors based on organic single-crystalline thin films have exceeded 10 cm²V⁻¹s⁻¹, respectively. (V. Podzorov et al., Physical Review Letter 93, 086602 (2004); H. Li et al., Journal of the American Chemical Society, 134, 2760 (2012)). Moreover, the organic single-crystalline thin film has a regular morphology, which is beneficial for device preparation and performance characterization.

The organic single-crystalline heterojunction refers to the heterojunction in which each of the components is single-crystalline form. The advantages of organic single-crystalline heterojunction are the excellent charge carrier transportation and long-range exciton diffusion brought by the highly ordered molecular arrangement. (H. Najafov et al., Nature Materials, 9, 938 (2010)). The highly molecular ordering exists not only in the bulk organic single crystal of each component, but also in the heterointerface where the two components are intimately contacted in the organic heterojunction. For OSCs, it benefits the separation of photogenerated excitons and the efficient charge carrier transportation in the donor/acceptor, which could improve the power conversion efficiency of OSCs. For organic field-effect transistors, the organic single-crystalline heterojunction aforementioned is conducive to ambipolar transportation in the devices, which is promising for preparing high-performance logic circuits. On this basis, the organic single-crystalline heterojunction with multi-layer/multi-component has enormous potential to realize more complicated optoelectronic functions.

However, since the organic single crystals constituting the organic single-crystalline thin film require strictly periodic molecular packing, the growth of the organic single crystals needs extraordinary control. Thus, it is very difficult to prepare organic single crystals. Moreover, it is even more difficult to stack/laminate different organic single crystals together. Therefore, in the prior art, few of organic single crystals could be prepared for constructing organic single-crystalline heterojunctions. It is well known to those skilled in the art that if the material state recited in the prior art is not single crystal/single-crystalline, the crystalline form is considered as polycrystalline without further elaboration.

The heterointerface/heterojunction interface/heterogeneous interface is formed between two different organic single-crystalline films constituting the heterojunction, since the components at both sides of the interface are organic single-crystalline thin film, the heterojunction interface is also called organic single-crystalline heterojunction interface (As shown in FIG. 1, it is marked as an organic single-crystalline heterojunction interface). Both the charge carrier transportation and exciton dissociation in the organic single-crystalline heterojunction occur at the heterojunction interface. Since the quality of the heterojunction interface plays a decisive role in the performance and power coversion efficiency of optoelectronic devices (N. Koch, ChemPhysChem, 8, 1438 (2007)). It is necessary to realize precise control over the quality of the heterojunction interface. To precisely control the quality of the ideal organic single-crystalline heterojunction, the following three requirements should be fulfilled at the same time: the highly-ordered heterojunction interface, the highly efficient lamination of the heterojunction interface as well as the two-dimensional high coverage of organic single-crystalline thin film.

In a first aspect, a highly-ordered heterojunction interface needs to be formed by stacking/laminating the organic single-crystalline thin films in the organic single-crystalline heterojunction. Due to the strict requirement for periodic molecular packing in the organic single crystals, the high degree of molecular ordering could be ensured at the heterojunction interface and in the bulk organic single-crystalline thin film located on the both sides of the heterojunction interface. Therefore, the overall high molecular ordering could be realized in the organic single-crystalline heterojunction, so as to provide a synergetic combination of multiple electronic and optoelectronic functions, which is the prerequisite for realizing the unique and excellent optoelectronic functions of the organic single-crystalline heterojunction. For a bi-component organic single-crystalline heterojunction, two layers of organic single-crystalline thin films are stacked/laminated together to form the laminated construction/configuration/structure. And efficient charge carrier transport could be achieved at its highly-ordered heterojunction interface. In addition, two adjacent layers of organic single-crystalline thin films as highly-ordered active materials are also in favor of the efficient charge carrier transport within the bulk materials. Any damage to the highly-ordered organic single-crystalline thin film and/or the heterojunction interface will severely impact the overall high molecular ordering of the organic single-crystalline heterojunction. For example, the single-crystallinity of one or two organic single-crystalline thin films is destroyed within partial morphology, and the crystalline form will be changed to polycrystalline or amorphous form if serious physical damage occurs at the heterojunction interface in the process of heterojunction preparation. Also, the organic singsle-crystalline thin films at both sides of the heterointerface suffered from interaction between each other could lead to similar result. In the end, the overall high molecular ordering of the organic single-crystalline heterojunction is deteriorated, the efficient charge carrier transport cannot be achieved. Thus, it is very difficult to realize excellent optoelectronic performance.

In a second aspect, in order to achieve a multiple-functional array of optoelectronic devices with high quality, high integration, and high efficiency, it is necessary to ensure the high degree of molecular ordering and satisfy the high-efficient lamination of the heterojunction interface at the same time. That is, the lamination area of the organic single-crystalline heterojunction should be as large as possible. The lamination area refers to the contact area between two adjacent organic single-crystalline thin films that constitute the organic single-crystalline heterojunction. The lamination area can reflect the actual working area of interface in the organic single-crystalline heterojunction, not only determines the number of carriers that can be detected, but also affects the operating voltage required for the target optoelectric effect. Therefore, to realize the control of the heterojunction interface quality, the size of the lamination area should be under precisely control, in order to obtain lamination area as large as possible.

Furthermore, for accurate description of the lamination area, a lamination area ratio R is applied. The smaller the lamination area ratio is, the smaller the contact area in the organic single-crystalline heterojunction is. The smaller contact area in the organic single-crystalline heterojunction means that the total number of charge carriers obtained will be reduced. This is detrimental for sensitive detection and operation of low-energy-consumption devices. For example, for a photodetector, to obtain a significant photocurrent, it is necessary to enlarge the applied operating voltage range, which greatly increases the energy consumption. (K. Park et al., Angewandte Chemie International Edition, 55, 10273 (2016)). The lamination area ratio R=Aₜₒₜₐₗ/A_{large}, where Aₜₒₜₐₗ refers to the contact area of the two adjacent organic single-crystalline thin films constituting the organic single-crystalline heterojunction, and A_{large} refers to the area of the larger organic single-crystalline thin film M_{L} in the two layers. As shown in FIG. 2A-FIG. 2E (both from the top view), the organic single-crystalline thin film with a larger area in the organic single-crystalline efficiently coupled unit is marked with M_{L}, and its area is A_{large} represented by gray color. The organic single-crystalline thin film with a smaller area is marked with M_{S}, and its area is Aₛₘₐₗₗ represented by white color. FIG. 2A-FIG. 2C are schematic diagrams of the lamination of two crystals (one crystal is from M_{L}, the other is from M_{S}). FIG. 2D is a schematic diagram of the lamination area of multiple crystals overlapping in the form of FIG. 2A. FIG. 2E is schematic diagram of the overlapping area of the multiple crystals in the form of FIG. 2C. Aₜₒₜₐₗ represents the lamination area, which is the area of the overlapping part between M_{L} and M_{S}, and also the overlapping part of A_{large} and Aₛₘₐₗₗ represented by black color. The black part aforementioned is the overlapping of the gray part and the white part. In FIG. 2A and FIG. 2D, the lamination area is equal to the area of the M_{S}, Aₜₒₜₐₗ=Aₛₘₐₗₗ. Since it observed from the top view, the black part and the white part are overlapped here, thus only black color is used for the overlapping area. Since the organic single crystals constituting the organic single-crystalline thin film require strictly periodic molecular packing, the growth of the organic single crystals needs extraordinary control. It has been very difficult to prepare the organic single-crystalline heterojunction via the prior art. Without destroying the organic single-crystalline heterojunction interface, it is even more difficult to achieve precise control of the lamination between the organic single-crystalline thin films. In the organic single-crystalline heterojunction, the stacking/laminating methods between two organic single crystals usually include but are not limited to cross-stacked (FIG. 3A), bilayer (FIG. 3B), lateral-stacked (FIG. 3C), axial-stacked (FIG. 3D), core-shell stacked (FIG. 3E), and branched (FIG. 3F). Among them, the lamination area obtained by cross-stacked, axial-stacked and branched is dot-shaped. For the lateral-stacked one, the lamination area obtained is in linear shape within the nano-scale range, and the size of lamination area is from a few nanometers to a few hundred nanometers in general. And the longest size of the organic single crystal is generally from a few microns to tens of microns or even larger. Through size comparison, it can be inferred that the actual lamination area ratio R is quite small, far less than 50%, which cannot meet the demand for ideal organic single-crystalline heterojunctions. In the core-shell stacked organic single-crystalline heterojunction (FIG. 3E), although one type of organic single crystal is partially covered on the outside of another organic single crystal, the morphology of crystals is irregular one-dimensional nanowire. As shown in FIG. 1B and FIG. 2 in Q. Cui et al., Advanced Materials, 24, 2332, (2012), the non-uniform morphology of nanowires can be clearly observed. This irregular morphology and perpendicular growth to the substrate will cause bending or even breaking down for the core-shell stacked organic single-crystalline heterojunction during the growth process. Thereby, it is unable to obtain an organic single-crystalline heterojunction with highly efficient lamination and continuous growth, which leads to difficulties in subsequent preparation of devices. The lamination area of the organic single-crystalline heterojunction obtained by the bilayer method (FIG. 3B) is in planar shape, which can achieve hundreds of microns or even larger. The lamination area ratio is also the largest among the above-mentioned stacking methods. Therefore, bilayer stacking is the most ideal method to achieve highly efficient lamination of organic single-crystalline heterojunctions rather than others. In addition to the bilayer stacking, other methods cannot obtain a larger lamination area, or even achieving the highly efficient laminating of the organic single-crystalline heterojunction.

Besides, by controlling two organic single-crystalline thin films to obtain the oriented lamination, the lamination area ratio could be further increased. Taking the organic single-crystalline heterojunction composite films in FIG. 2D and FIG. 2E as the examples, the orientation of the two layers of organic single-crystalline thin films in FIG. 2D is well-aligned, that is, they are almost parallel. However, in FIG. 2E, the two organic single-crystalline thin films have inconsistent orientations, and the two organic single crystal arrays stagger together (for example, as shown in FIG. 1i in J. K. Wu et al., Advanced Materials, 27, 4476 (2015), the schematic diagram is close to the cross-stacked method shown in the FIG. 3A), compared with FIG. 2D, the lamination area ratio is greatly reduced. The bilayer lamination could maintain a consistent orientation, which ensure the lamination area ratio as large as possible, furthermore, high-performance optoelectrical behaviors can be realized by the organic single-crystalline heterojunction. The organic single-crystalline heterojunctions those satisfied highly efficient lamination already have multiple merits, providing high-quality platform for excellent electronic and/or optoelectronic performance.

In a third aspect, the efficient transport of charge carriers requires the area of channel to be as large as possible, so it is necessary to precisely control the organic single-crystalline thin film in the organic single-crystalline heterojunction to achieve two-dimensional high coverage. Specifically, it means that the organic single-crystalline thin film needs to be able to achieve high coverage on the substrate in two dimensions (referred as two-dimensional high coverage), that is, both the vertical coverage ratio (R_{V}) and the horizontal coverage ratio (R_{H}) of the organic single-crystalline thin film are sufficiently large. The vertical coverage ratio refers to the ratio of the continuous length of the organic single-crystalline thin film to the length of the substrate in the direction V (the direction V is along the crystal growth direction), and the horizontal coverage ratio refers to the ratio of the sum of the crystal width to the width of the substrate in the direction H (the direction H is perpendicular to the crystal growth direction). Specifically, the two-dimensional high coverage means that the organic single-crystalline thin film has a sufficiently high coverage ratio in both the direction V and the direction H. That is, when the vertical coverage ratio (R_{V}) in the direction V is greater than or equal to 80% and horizontal coverage ratio (R_{H}) in the direction H is greater than or equal to 70%, it can be considered that the two-dimensional high coverage is satisfied, and a high-quality channel for charge carrier transportation for organic single-crystalline thin film is provided, which is one of the important factors that determine the device performance. Moreover, the larger the vertical coverage ratio and the horizontal coverage ratio is, the larger the lamination area of the organic single-crystalline heterojunction interface is for a constant lamination area ratio. That is, by accurately controlling the organic single-crystalline thin film to achieve two-dimensional high coverage, it can further ensure the highly efficient lamination at the interface of the organic single-crystalline heterojunction. In summary, the high molecular ordering of the heterojunction interface, the highly efficient lamination of the heterojunction interface, and the two-dimensional high coverage of the organic single-crystalline thin film are combined synergistically and none of these conditions aforementioned can be split or missing. Satisfying the first two conditions could obtain the organic single-crystalline heterojunction with good performance, but only satisfying the three conditions simultaneously is the prerequisite for obtaining an ideal organic single-crystalline heterojunction and related optoelectronic devices or even device arrays with more sophisticated structure.

The crystalline form of each component of the organic single-crystalline heterojunction is single crystal. It is extremely difficult to control the growth of single crystals, since the molecules need to be regularly and periodically arranged in a three-dimensional space in the single crystal. Therefore, the growth of organic single crystals is much more difficult compared with their polycrystalline and amorphous states. The extraordinary control over the microstructure and morphology are required for organic single crystals, which is very difficult to realize (M. Niazi et al., Advanced Functional Materials, 26, 2371 (2016)). For organic single-crystalline heterojunctions, two or more organic single crystals need to be obtained. Additionally, highly ordered bulk organic single crystal as well as organic single-crystalline heterojunction interface must be ensured at the same time. That is, the damage on the organic single-crystalline thin films that form the organic single-crystalline heterojunction composite film should be avoided when they are in contact with each other. Besides, at least two layers of organic single-crystalline thin films intimately contacted with each other in a consistent orientation should be guaranteed. And the above-mentioned two or more organic single crystals need to have lamination area ratio as large as possible, moreover, at least one organic single-crystalline thin film needs to achieve two-dimensional high coverage. However, precise control of the three factors aforementioned is the major problem that cannot be solved by the existing technology. For obtaining the organic single-crystalline heterojunction with ideal morphology, the three factors aforementioned influence each other and lead to a mutual effect, thus they cannot be separated. When the precise control of the first two factors is realized, a high-quality organic single-crystalline heterojunction composite film can be obtained, and its morphology and device performance have been greatly improved compared with the current technology. On this basis, an organic single-crystalline heterojunction composite film with an ideal morphology could be gained only the three factors aforementioned are precisely controlled at the same time. For example, the requirements for the high degree of ordering at both the interface and bulk of the organic single-crystalline heterojunction seriously limit the manufacturing process. In addition, strict control over the crystal growth process is also required, which makes the prior art unable to achieve highly efficient lamination in organic single-crystalline heterojunctions and two-dimensional high coverage within at least one layer of organic single-crystalline thin film. For another example, when the organic single-crystalline thin film cannot achieve two-dimensional high coverage, the coverage area of the organic single-crystalline thin film is severely restricted, which makes it difficult to obtain an enough lamination area when forming an organic single-crystalline heterojunction with two or multiple layers of organic single-crystalline thin films, therefore, it is impossible to achieve highly efficient lamination. Therefore, in order to obtain an organic single-crystalline heterojunction with the most ideal morphology, it is necessary to achieve a highly ordered heterojunction interface, highly efficient lamination of the heterojunction interface, and two-dimensional high coverage of organic single-crystalline thin film simultaneously. However, accurate control of the three factors aforementioned cannot be achieved in the current technology.

Nowadays, organic single-crystalline heterostructures are mainly prepared by mechanical transfer method, vapor phase epitaxy method, solution-processed method including two-step growth as well as one-step growth method in the prior art. The mechanical transfer method is a preparation method in which the separately grown organic single-crystalline components are combined by physical means, such as overlaying technique, peeling transfer technique, etc. It has been reported that the overlaying technique is used to superimpose flexible organic single crystals through mechanical transferring to form organic single-crystalline heterojunctions with top-bottom structures. This technology requires the surface of organic single crystals in the bottom layer to be sufficiently flat, and the top organic single crystals need to be sufficiently flexible to conform on the bottom ones. However, only individual organic single-crystalline heterojunctions can be obtained, the continuous organic single-crystalline heterojunction thin films are not available, as shown in FIG. 3 in H. Alves et al., Nature materials, 7, 574 (2008). In addition, the bilayer organic single crystals in the obtained organic single-crystalline heterojunction are interlaced with each other, and the discontinuous morphology is exhibited, the related schematic diagram is shown in FIG. 2B of the present disclosure. By directly observing the FIG. 3c in H. Alves et al., Nature materials, 7, 574 (2008) and calculating the lamination area ratio with ImageJ or other image analysis software, it is clear that the lamination area ratio R between the two organic single crystals is very small, much less than 50% (The ratio of the lamination area between the orange long single crystal (TTF, tetrathiofulvalene) and the yellow square-like single crystal (TCNQ, 7,7,8,8-tetracyanoquinodimethane) to the larger yellow single crystal is about 1:4). Moreover, this technology requires high-precision control and complicated operation for the subsequent preparation of devices, thereby, the large-scale production cannot be achieved through mechanical transfer method. Since the overlaying is in a physical/mechanical way, the overlaying between the two organic single crystals cannot guarantee the high quality of the heterojunction interface, the damage to the single crystals themselves during the overlaying process will decrease the quality of the heterojunction interface (especially the degree of ordering), and the impurities may even be introduced, thereby destroying the high degree of ordering at the heterojunction interface. Although the mechanical transfer method can realize transferring the independently grown crystals together, the critical problem of maintaining the integrity of the heterointerface during the transfer process is still not yet resolved. Besides, it is very easy to damage the grown organic single-crystalline thin film during the transferring, which is unworthy.

Epitaxial growth from vapors can be used to prepare organic single-crystalline heterojunctions, however, because organic semiconductor single crystals usually have anisotropic crystal shapes and the van der Waals forces between molecules are weak, it is very difficult to achieve epitaxial growth. Thus, only specific types of organic molecules could realize vapor phase epitaxial growth to obtain organic single-crystalline heterojunctions, which are mostly irregular one-dimensional nanowires (Q. H. Cui et al., Advanced Materials, 24, 2332 (2012)). The lamination area ratio and effective lamination area between the two organic single crystals are very small. According to the FIG. 1D in Q. H. Cui et al., Advanced Materials, 24, 2332 (2012), by using image analysis software (such as ImageJ) to analyze the ratio of the diameters of copper phthalocyanine (CuPc) and 5, 10, 15, 20-tetra (4-pyridyl)-porphyrin (H₂TPyP) nanowires, ultimately, the lamination area ratio R calculated is less than 5%. In addition, the coverage of organic single-crystalline thin films obtained by epitaxy growth method from vapors is too small for constituting the organic single-crystalline heterojunction, meanwhile the two-dimensional high coverage as well as large-area continuous growth cannot be realized. Also, the epitaxy growth method from vapors consumes a lot of energy, the preparation requirements for equipment and production cost are quite strict, which cannot meet the needs of industrialization.

The solution method can realize the large-area preparation for organic single crystals. It has been reported that the two-step solution growth method was used to grow a second layer of organic single crystals on the first pre-deposited layer of organic single crystals. The most critical step is to use an orthogonal solvent to prevent the growth process of the second single crystals from damaging the first single crystals. Some representative cases are shown in J. K. Wu et al., Advanced Materials, 27, 4476(2015) and X. Zhao et al., ACS Applied Materials & Interfaces, 10, 42715(2018), the casting method is used to prepare double-layer single crystals. Because the second layer of crystals needs to stride over the first layer of crystals during the growth, therefore, the growth of the second layer of crystals is greatly affected by the thickness and the crystal surface properties (including the chemical and physical aspect) of the first layer of crystals. The growth direction of the second layer of crystals is disturbed, and a certain angle difference with the growth direction of the first layer of crystals will be formed. Finally, the staggered type of growth will be exhibited, the diagram is shown in FIG. 2C and FIG. 2E. For example, by directly observing the FIG. 2(b) in X. Zhao et al., ACS Applied Materials & Interfaces, 10, 42715(2018), the SEM image showing the morphology of the organic single-crystalline heterojunction in a specified area, it can be clearly distinguished that the lamination area between the two organic single crystals is very small, and which is unable to achieve the two-dimensional high coverage of the organic single-crystalline thin films for constituting the organic single-crystalline heterojunction. Chinese patent No. CN108342779A discloses a method for growing a micro-belt single-crystalline p-n heterojunction array, this method needs to prepare a precisely patterned substrate in advance, which has high energy consumption and high production cost. Moreover, the horizontal coverage ratio of the organic single-crystalline heterojunction thin film obtained is low, which cannot meet the requirement of two-dimensional high coverage as mentioned above. It has been mentioned in the Chinese patent No. CN108342779A that “the photoresist stripes 120 are spaced apart on the substrate 110, and the hydrophobic monomolecular layer 130 is formed on the substrate 110.” Combined with the FIG. 3 in CN108342779A, it can be clearly observed that the area of the channel is half occupied by the photoresist stripes after the substrate is patterned, and the obtained organic single-crystalline heterojunction thin film grows along the edges of the patterned template protrusions (photoresist stripes). Thus, the area that can be horizontally covered is greatly limited, and it is impossible to obtain an organic single-crystalline thin film achieving the two-dimensional high coverage in the channel. It is well known by those skilled in the art that the active layer in the optoelectronic device (for example, an organic single-crystalline thin film composed of organic semiconductor molecules) can realize effective electric and/or optoelectric effects in the channel. Besides the channel, there may be other deposits on the substrate (for example, a patterned template composed of photoresist stripes). Another example is the article (W. Deng et al., ACS Applied Materials & Interfaces, 11, 39 (2019)) published by the inventor of the Chinese patent (CN108342779A), FIG. 2e in the article shows an optical microscopic image of a specified area of the single-crystalline heterojunctions on the substrate, in which the gray strips are the protrusions in the patterned template, the direction parallel to the gray strips is the direction V, which is also the direction of crystal growth, and the direction perpendicular to the gray strips is the direction H. By using image analysis software such as Image J for analysis, in the direction H, the ratio of the sum of the crystal width to the gullies (here referred to as channels) without gray strips can be directly calculated as the horizontal coverage ratio R_{H, channel}, and R_{H, channel} is <30%. In the direction H, the ratio of the total width of the crystals to the entire substrate (including the gray strips) is calculated as the overall horizontal coverage ratio R_{H}, and R_{H}<15%. Since the obtained horizontal coverage ratio in the gullies is already relatively low, the horizontal coverage ratio on the whole substrate is much lower. Thereby, the two-dimensional high coverage of the organic single-crystalline thin film cannot be achieved, which severely restricts the performance of the device array. On the other hand, for preparing large-area organic single crystals via solution method, good solubility is required for the organic molecules (solutes) in organic solvents, otherwise the mass transport of the solutes will be constrained and the growth of crystals will be influenced. For adopting a two-step method to prepare the organic single-crystalline heterojunction composite film, it is necessary to find an orthogonal solvent that does not dissolve the first layer of organic crystals while still has good solubility for the organic molecules of the second layer. Therefore, the choice of materials and solvents is restricted to a quite narrow range, it is almost impossible to prepare organic single-crystalline heterojunctions composed of more than two organic single-crystalline thin films. Moreover, the damage to the upper surface of the first layer of crystals during the growth of the second layer of crystals is inevitable, which impacts the quality of the heterojunction interface as well. Different from the two-step method, the one-step method prepares two organic semiconductor molecules in one mixed solution, thus the organic single-crystalline heterojunction can be directly grown at one time. It not only simplifies the growth process, but also realizes the synergistic combination of two organic single crystals. The one-step method can directly avoid damage to the crystal surface of the first layer during transferring or preparation of the second layer of single crystals, moreover, the in-situ growth of organic single-crystalline heterojunction thin film could be achieved. Although the inventors tried to use the droplet-pinned crystallization method (referred to as DPC method) to realize the one-step preparation of organic single-crystalline heterojunction composite film in the early exploration by using a mixed solution to obtain the double-layer organic single-crystalline heterojunction (H. Li et al., Angewandte Chemie International Edition, 54, 956(2015); H. Li et al., Journal of the American Chemical Society, 141, 25(2019)), the morphology had not been effectively controlled, still showing the staggered type growth. The schematic diagrams are shown in the FIG. 2C and FIG. 2E, uncomplete covering is displayed between the upper and lower crystals in the organic single-crystalline heterojunction with staggered growth morphology, visible gaps are clearly shown in the lamination (as shown in FIG. 18A and FIG. 18B, there are gaps existed between the crystals). The maximum lamination area ratio is limited, and the requirements of highly efficient lamination for ideal organic single-crystalline heterojunctions cannot be fulfilled. The FIG. 2a in H. Li et al., Angewandte Chemie International Edition, 54, 956 (2015) and FIG. 5e in H. Li et al., Journal of the American Chemical Society, 141, 25 (2019) are shown in FIG. 18A and FIG. 18B of the present disclosure respectively, displaying the optical microscopic images of the small-scale characterization of the organic single-crystalline heterojunction morphology. The irregular crystal morphology can be clearly seen, which includes but not limits to uneven crystal orientation, bifurcation, and width changes. Image analysis software (such as ImageJ) is used to count the C₆₀ crystals in FIG. 2a of H. Li et al., Angewandte Chemie International Edition, 54, 956 (2015) (also shown in FIG. 18A of the present disclosure). In the direction H (that is, the direction perpendicular to the light yellow strips in FIG. 2a, here the light yellow strips represent the C₆₀ crystals), the proportion of total crystal width to substrate is accounted for the horizontal coverage ratio of the thin film. For the thin film composed of C₆₀ crystals, which have a larger area, the horizontal coverage ratio R_{H} is about 67%. Another kind of thin film composed of 3,6-bis(5-(4-n-butylphenyl)thiophene-2-yl)-2,5-bis(2-ethylhexyl)pyrrolo[3,4-c] pyrrole-1,4-dione (DPP-PR) crystals has only 4 crystals in FIG. 18B, thus no statistically significant data can be obtained. Similarly, the image analysis software (such as ImageJ) is also applied to analyze the FIG. 5e of H. Li et al., Journal of the American Chemical Society, 141, 25 (2019) (also shown in FIG. 18B of the present disclosure). After counting the only crystals in FIG. 18B (note that there are only 6 crystals in FIG. 18B, actually it is difficult to obtain statistically significant data, thereby the obtained data here is only for comparison), in the direction H (that is, the direction perpendicular to the yellow strips in FIG. 5e, the yellow strips represent the crystal), the horizontal coverage ratio R_{H} of the crystals with larger area is about 65%. In a conclusion, the organic single-crystalline thin film obtained by the DPC method cannot realize the crystal growth with two-dimensional high coverage. Although the growth of organic single-crystalline heterojunction by applying the above-mentioned solution method (including two-step method and one-step method) could realize the combination of different types of organic single-crystalline thin films, the morphology of the organic single-crystalline heterojunction thin film still lacks precise control, moreover, the ideal morphology cannot be achieved.

In summary, the most ideal organic heterojunction film that could be produced on a large-scale for the further industrial application contains a heterojunction interface with high degree of ordering and highly efficient lamination, and a two-dimensional high coverage can also be realized. The organic single-crystalline heterojunction film aforementioned comprises at least two layers of organic single-crystalline thin films from different materials, and the two layers are laminated together, in order to ensure the heterojunction interface achieving the ideal high degree of ordering; the highly efficient lamination between the two adjacent organic single-crystalline thin films ensures that the lamination area ratio is large enough, so that the heterojunction interface can enable the diversified electrionic/optoelectronic or other special functions for optoelectronic devices based on the organic single-crystalline heterojunction film; the organic single-crystalline thin film with two-dimensional high coverage can meet the needs of maximizing the device performance, realizing industrial production as well as the preparation of highly integrated device arrays. However, the existing technology cannot produce the aforementioned organic single-crystalline heterojunction film, and there are the three huge challenges as follows: 1) during the growth process of the organic heterojunction film, taking the double-layer organic single-crystalline heterojunction as an example, the second layer of organic single-crystalline thin film needs to be grown or overlapped on the pre-deposited first layer of organic single-crystalline thin film, it is easy to damage the surface of the first layer, thus a high-quality and highly ordered heterojunction interface cannot be formed; 2) because the organic single-crystalline thin film requires strictly periodic molecular arrangement, the requirement for growth environment is extremely strict, and the growth of the second layer of organic single crystals is seriously affected by the first layer, suffering from the crystal thickness of the first layer, as well as the physical and chemical properties of the crystal surface in the first layer, eventually, the growth direction is severely disturbed, the interlaced growth occurs, and the crystal quality is greatly reduced, furthermore, the heterojunction interface with the largest possible lamination area ratio cannot be obtained; 3) the morphology of the organic single-crystalline thin film is difficult to control, and the two-dimensional high coverage of at least one organic single-crystalline thin film cannot be achieved while maintaining the single-crystallinity of the adjacent double layers. Therefore, how to obtain an ideal organic single-crystalline heterojunction composite film with a high degree of ordering, highly efficient lamination, and two-dimensional coverage is a huge technical problem, and it is also the biggest obstacle for the optoelectronic devices based on the organic single-crystalline heterojunction composite film to obtain multi-function realization integration and industrialization at the same time. The existing technology cannot break through the above-mentioned obstacles.

### SUMMARY

In view of the shortcomings of the prior art, the technical problem to be solved by the present disclosure is to provide a high-quality organic single-crystalline heterojunction composite film containing a heterojunction interface with high degree of ordering and highly efficient lamination. Furthermore, it is another object of the present disclosure to realize a two-dimensional high coverage of the organic single-crystalline thin film. As such, an organic single-crystalline heterojunction composite film with an ideal morphology that simultaneously meets the above three requirements is provided. Also, the object of present invention is to provide a preparation method thereof and an optoelectronic device array comprising the aforementioned organic single-crystalline heterojunction composite film. The organic single-crystalline heterojunction composite film can achieve high performance of charge carrier transportation and long-range exciton diffusion at the same time, and varied optoelectronic functions could be integrated on a common device array; the easy-control of the morphology of the single crystal, the good stability, and the simple preparation method can satisfy large-area preparation and further integration on flexible substrates in industry.

Based on the existing problems of the prior art, inventors overcome the numerous obstacles of the prior art and successfully prepared the high-quality organic single-crystalline heterojunction composite film with high-quality interface and highly efficient lamination, the morphology and device performance of the organic single-crystalline heterojunction composite film have been greatly improved compared with the prior art. Furthermore, on this basis, a high coverage (two-dimensional high coverage) of organic single-crystalline thin film is realized, and the organic single-crystalline heterojunction composite film with the ideal morphology achieving three aspects aforementioned is obtained. The three huge challenges that cannot be solved by the prior art for growing organic single-crystalline heterojunction could be overcome by the present disclosure at the same time. The organic single-crystalline heterojunction composite film prepared by the present disclosure satisfies the ideal state of both the morphology and the material, and is the key to realize the ideal state of industrialized multifunctional organic semiconductor optoelectronic devices: the organic single-crystalline heterojunction composite film provides a high-quality channel with a maximized area for effective charge dissociation and efficient charge carrier transport. The organic semiconductor optoelectronic devices based on the organic single-crystalline heterojunction composite film have multilple merits, including the highest performance of charge carrier transport, the longest exciton diffusion length, the highest degree of integration, the widest range of optional materials, and the simplest preparation method for the industry. Meanwhile, it lays a solid foundation for the large-scale industrial preparation of the above-mentioned organic single-crystalline heterojunction thin films with almost ideal states as well as related semiconductor devices, and overcomes the huge obstacles of the prior art.

The present disclosure is realized by the following technical solutions:

The first technical problem to be solved by the present disclosure is to provide an organic single-crystalline heterojunction composite film, which comprises M organic materials, and M is a positive integer greater than or equal to 2; the organic single-crystalline heterojunction composite film comprises a laminated structure (laminated construction/configuration/structure), and the laminated structure refers to the organic single-crystalline heterojunction composite film is composed of N layers of organic single-crystalline thin films stacked in sequence, and N is a positive integer greater than or equal to 2; the organic single-crystalline thin film is composed of the organic single crystal array; the organic single crystal array is composed of multiple crystals, and the crystals are single-crystalline; the organic single-crystalline heterojunction composite film comprises at least one organic single-crystalline efficiently coupled unit; the organic single-crystalline efficiently coupled unit is composed of an organic single-crystalline thin film MT and an organic single-crystalline thin film MB, and the organic single-crystalline efficiently coupled unit has highly efficient lamination; the highly efficient lamination means that the organic single-crystalline efficiently coupled unit has a sufficiently high ratio of lamination area; MT and MB are laminated together, the materials constituting MT and MB are different. The schematic diagram of the structure is shown in FIG. 1.

The organic single-crystalline heterojunction composite film comprises a laminated structure, and specifically refers to at least one organic single-crystalline efficiently coupled unit in which two organic single-crystalline thin films are laminated together (as shown in FIG. 3B). When N≥3, that is, for multi-layer and multi-component organic single-crystalline heterojunction composite film, the third layer or other multi-layer organic single-crystalline thin films can be laminated together or combined by other measure. For example, the other measure includes but not limited to by any one or more methods shown in FIG. 4.

The values of M and N could be equal or unequal. When M is less than N, it is necessary to ensure that the adjacent organic single-crystalline thin films consisted by different materials. For example, if N=3 and M=2, the laminated structure of the organic single-crystalline heterojunction composite film can be ABA or BAB (where A and B represent organic single-crystalline thin films with different composition material, respectively).

The organic single-crystalline heterojunction composite film comprises at least one organic single-crystalline efficiently coupled unit, which specifically means that the number of organic single-crystalline efficiently coupled unit in the organic single crystal heterojunction composite film is greater than or equal to 1. The number of organic single-crystalline efficiently coupled units depends on the number of two adjacent organic single-crystalline thin films that can achieve highly efficient lamination. The maximum number is (that is, any two organic single-crystalline thin films selected from the N layers capable of achieving highly efficient lamination, C_{N}²=N×(N−1)/(2×1)); if N=2, the number of organic single-crystalline efficiently coupled unit is 1; if N=3, the number of organic single-crystalline efficiently coupled unit can be 1, 2 or 3; if N=4, the number of organic single-crystalline efficiently coupled unit can be 1, 2, 3, 4, 5 or 6. Also, the organic single-crystalline heterojunction composite film can also be composed of only one organic single-crystalline efficiently coupled unit.

The highly efficient lamination of the organic single-crystalline efficiently coupled unit refers to the lamination area ratio R≥50%. The lamination area ratio R=Aₜₒₜₐₗ/A_{large}, Aₜₒₜₐₗ refers to the lamination area between the two organic single-crystalline thin films which constitute the organic single-crystalline efficiently coupled unit, A_{large} refers to the area of the larger one in the two thin films; preferably, R≥60%; preferably, R≥70%; preferably, R≥80%; preferably, R≥90%; most preferably, R=100% (that is, Aₜₒₜₐₗ=A_{large}).

In some embodiments, the detection method of the lamination area ratio R is randomly selecting m adjacent crystals in the organic single-crystalline film M_{L} (a larger one in the two layers) in the organic single-crystalline efficiently coupled unit, R=Aₜₒₜₐₗ/A_{large}, A_{large} is the total area of the m crystals, A_{large}=A_{large1}+A_{large2}+ . . . +A_{largem}, where A_{large1}, A_{large2}, . . . A_{largem} represent the area of the 1, 2, . . . , m crystal, respectively; A_{large} is the total lamination area of the m crystals, Aₜₒₜₐₗ=Aₜₒₜₐₗ₁+Aₜₒₜₐₗ₂+ . . . +Aₜₒₜₐₗm, where Aₜₒₜₐₗ₁, Aₜₒₜₐₗ₂, . . . Aₜₒₜₐₗₘ represent the lamination area of the 1, 2, . . . , m crystal, respectively; m is a positive integer greater than or equal to 7. As shown in FIG. 2, the organic single-crystalline thin film with a larger area in the organic single-crystalline efficiently coupled unit is M_{L}, A_{large} is the area of M_{L} represented by gray color, and the organic single-crystalline thin film with a smaller area in the organic single-crystalline efficiently coupled unit is M_{S}, Aₛₘₐₗₗ is the area of M_{S} represented by white color. FIG. 2A-FIG. 2C is the schematic diagrams of the lamination of M_{L} and M_{S}. FIG. 2D is the schematic diagram of the overlapping area of multiple crystals in the form of FIG. 2A. FIG. 2E is the schematic diagram of the overlapping area of multiple crystals in the form of FIG. 2C. Aₜₒₜₐₗ represents the lamination area, which is the area of the overlapping part between M_{L} and M_{S}. Also, Aₜₒₜₐₗ is the overlapping part of A_{large} and Aₛₘₐₗₗ represented by black color, which is the overlapping of the gray part and the white part. In FIG. 2A and FIG. 2D, the lamination area is equal to the area of the M_{S}, herein Aₜₒₜₐₗ=Aₛₘₐₗₗ, where the black part overlapped by the white part, thus the lamination area is only represented by black color.

In some embodiments, in the organic single-crystalline efficiently coupled unit, at least one organic single-crystalline thin film has a two-dimensional high coverage. The two-dimensional high coverage refers to the vertical coverage ratio R_{V} of the organic single-crystalline thin film is >80% in the direction V (direction V is along the crystal growth direction), and the horizontal coverage ratio R_{H} is ≥70% in the direction H (direction H is vertical to the crystal growth direction). The R_{V} refers to the ratio of the continuous length of the organic semiconductor single-crystalline thin film to the substrate in the direction V, the R_{H} refers to the ratio of the total crystal width to the substrate in the direction H; preferably, R_{V}≥85%; preferably, R_{V}≥90%; preferably, R_{V}≥95%; preferably, R_{V}=100%; preferably, R_{H}≥75%; preferably, R_{H}≥80%; preferably, R_{H}≥85%; preferably, R_{H}≥90%. The continuity means that in the direction V, the crystals constituting the organic single-crystalline thin film are not completely disconnected.

In some embodiments, as shown in FIG. 5, the gray strips represent the crystals constituting the organic single crystal array. R_{V}=(l₁+l₂+ . . . +lₙ)/nL, where l₁, l₂, . . . , lₙ represent the length of the 1, 2, . . . , n crystals in the direction V, respectively, and L is the length of the substrate in the direction V; R_{H}=(w₁+w₂+ . . . +wₙ)/W, where w₁, w₂, . . . , wₙ represent the width of the 1, 2, . . . , n crystals in the direction H, respectively, W is the width of the substrate in the direction H, and n is a positive integer greater than or equal to 7.

The organic single-crystalline heterojunction composite film provided by the present disclosure has a multi-layer and multi-component structure, which provides a foundation for realizing diverse functions of high-performance organic semiconductor devices. The multiple electrionic and optoelectronic functions can be integrated in a single device, which is beneficial for increasing packaging density. The organic single-crystalline heterojunction composite film constructed by organic single-crystalline thin films, since the organic single crystal has advantages including the highest long-range ordering, higher purity, and fewer defects compared with other forms, a highly ordered heterojunction interface without grain boundaries is provided between any two adjacent organic single-crystalline thin films, which becomes the best platform to realize electrionic/optoelectronic functions such as recombination/separation of hole-electron pairs and injection/extraction of charge carriers. The ratio of the lamination area between the two adjacent organic single-crystalline thin films M_{T} and M_{B} in the organic single-crystalline heterojunction composite film affects the actual working area in the channel. If the lamination area ratio is too small, the performance of the optoelectronic devices is greatly restricted. Therefore, the larger the lamination area ratio is, the larger the actual working area is, and the better the optoelectronic performance of the device can be achieved. In the organic single-crystalline efficiently coupled unit of the present disclosure, at least two organic single-crystalline thin films are laminated together. The structure diagram is shown in FIG. 2A, FIG. 2D, FIG. 3B and FIG. 4B, where FIG. 2A and FIG. 2D are from the top view, FIG. 3B and FIG. 4B are three-dimensional schematic diagrams, it can be observed that bilayer or multilayer organic single crystals are laminated to form the organic single-crystalline heterojunction. Therefore, the heterojunction has a sufficiently high lamination area ratio (take FIG. 10 as an example, where FIG. 10B is the schematic diagram of FIG. 10A, after calculation, it can be obtained that the lamination area ratio exceeds 50%). Thereby, highly efficient lamination is achieved, ensuring the maximized electrical/optoelectrical behaviors occurring at the heterojunction interface as much as possible. The semiconductor devices based on the organic single-crystalline heterojunction composite film are capable of obtaining superior electrical/optoelectrical properties. In the organic single-crystalline efficiently coupled unit, at least one organic single-crystalline thin film could achieve two-dimensional high coverage, which means exhibiting high vertical and horizontal coverage. A high-quality channel for efficient charge carrier transport is provided, which greatly increases the density of carriers in the working devices. Moreover, a higher integration of multiple devices on the organic single-crystalline heterojunction composite film could be expected as well as further improvement on the electrionic/optoelectronic properties for application in industry.

In some embodiments, in the organic single-crystalline efficiently coupled unit, at least one organic single-crystalline thin film is composed of material selected from organic semiconductor molecules, and other layers of organic single-crystalline thin films (including one or more layers) can be selected from any one or more of organic semiconductor molecules, organic molecules with optoelectric properties, and organic molecules with ferroelectric properties. Preferably, the core of the organic semiconductor molecule has a π-conjugated system.

In some embodiments, the organic semiconductor molecules aforementioned are selected from any one or more of linear acenes and linear acenes derivatives, linear heteroacenes and linear heteroacenes derivatives, benzothiophene and benzothiophene derivatives, perylene and perylene derivatives, perylene diimides and perylene diimides derivatives, naphthalene diimides and naphthalene diimides derivatives, fullerene and fullerene derivatives. The derivative refers to a product formed by replacing atoms or groups of atoms in a compound molecule with other atoms or groups of atoms. For instance, both methanol (CH₃OH) and chloromethane (CH₃Cl) are derivatives of methane (CH₄). And the derivatives aforementioned can also contain cyano or halogen substituted compounds. The organic molecules with optoelectric or ferroelectric properties referring to the organic materials those have potential for exhibiting any one or more of optoelectric or ferroelectric behaviors.

Preferably, the adjacent bilayer organic single-crystalline thin films in the heterojunction are selected from p-type and n-type organic semiconductor molecules respectively. The organic semiconductor molecules for the bilayer contain a π-conjugated system in the core, side groups of alkane chain or silane chain, and more importantly, they have good solubility in the same solvent. The same solvent can be a single solvent or a mixed solvent of multiple components. With different types of organic semiconductor molecules, ambipolar charge carrier transport can be realized, and diversified optoelectronic functions can be achieved at the interface of heterojunction. Preferably, in a same solvent, crystallization rate difference are existed between the two molecules of the bilayer organic single-crystalline thin film in the organic single-crystalline efficiently coupled unit. It is beneficial for the second type of molecules to nucleate and grow on the pre-formed crystals, after the first type of molecules crystallization.

The organic semiconductor molecule refers to a material whose conductivity is between that of an organic conductor and an organic insulator. The π-conjugated system is a system wherein conjugated it-bonds are able to form. Materials with π-conjugated system have π-conjugated structures in their core, such as linear acenes, linear heteroacenes, benzothiophene, perylene, perylene diimides, naphthalene diimides, fullerene and their respective derivatives. Also, these materials possess good crystallinity, which is easy to obtain high-quality organic semiconductor single-crystalline thin films. For example, 6,13-bis(triisopropylsilylethynyl)pentacene (TIPS-PEN) and 2,7-dioctyl[1]benzothieno[3,2-b] benzothiophene (C₈-BTBT) have side groups such as silane chain (for TIPS-PEN) or alkane chain (for C₈-BTBT), leading to a high solubility in organic solvents, which is better for the two-dimensional high coverage growth of organic single-crystalline thin films. Thus, a large-area high-quality organic single-crystalline thin film can be obtained, and the highly efficient lamination between the bilayer organic single-crystalline thin films can be further realized in the organic single-crystalline efficiently coupled unit.

In some embodiments, the organic single-crystalline efficiently coupled unit has lamination coupling, and the lamination coupling refers to the lamination between the organic single-crystalline thin film M_{T} and the organic single-crystalline thin film MB are well-aligned/uniformly orientated.

In some embodiments, the well-aligned/uniformly orientated lamination means that the degree of laminated orientation F_{L}≥0.625; preferably, F_{L}≥0.70; preferably, F_{L}≥0.75; preferably, F_{L}≥0.80; preferably, F_{L}≥0.85; preferably, F_{L}≥0.90; preferably, F_{L}≥0.95; more preferably, F_{L}=1. The closer the laminated orientation is to 1, the closer the laminated orientation is to parallel. When F_{L}=1, the laminated orientation between the M_{T} and the M_{B} is completely consistent/parallel. As shown in FIG. 2A and FIG. 2B, the bilayer organic single crystal arrays are parallel to each other (the organic single-crystalline thin film is composed of organic single crystal arrays).

In some embodiments, the detection method of the laminated orientation degree F_{L}: in the organic single-crystalline efficiently coupled unit, n crystals are randomly selected as samples in the M_{T} and M_{B} respectively, and n is a positive integer greater than or equal to 7. Take the crystal growth direction as the reference direction, and take the angle between the direction of the longest dimension c_{T} of the crystal C_{T} in the M_{T} and the reference direction as the orientation angle A_{T}. Ā_{T} is the average orientation angle of the n crystals in M_{T}. Take the angle between the direction of the longest dimension c_{B} of the crystal C_{B} in the M_{B} and the reference direction as the orientation angle A_{B}, Ā_{B} is the average orientation angle of the n crystals M_{B}. The laminated orientation degree F_{L}=0.5*(3*cos²Ā−1), where Ā=(Ā_{T}−Ā_{B}). As shown in FIG. 6A, the white strip represents the crystal C_{T}, and the gray strip represents the crystal C_{B}, the direction V is along the crystal growth, and the direction H is perpendicular to the crystal growth.

The method for detecting the orientation angle is to use software that can analyze image pixels (such as Image J, Matlab, Photoshop, Adobe Illustrator, etc., the present disclosure takes Image J as an example). The orientation angle can be obtained by analyzing the morphology or microstructure of the organic single-crystalline thin film through the optical microscopic image, and after subsequent calculations the laminated orientation degree could be obtained.

The second object of the present disclosure is to provide a method for preparing an organic single-crystalline efficiently coupled unit, which is obtained by laminating coupled growth method. The laminating coupled growth method referring to synergistic growth realized by M_{T} and M_{B} to acquire the organic single-crystalline efficiently coupled unit along the crystal growth direction. The organic single-crystalline efficiently coupled unit aforementioned is composed of the organic single-crystalline thin film M_{T} and the organic single-crystalline thin film M_{B}, with highly efficient lamination. M_{T} and M_{B} are laminated together, and the materials constituting the M_{T} and M_{B} are different. The highly efficient lamination of the organic single-crystalline efficiently coupled unit refers to the lamination area ratio R is ≥50%, R=Aₜₒₜₐₗ/A_{large}, Aₜₒₜₐₗ refers to the area between the two organic single-crystalline thin films in the organic single-crystalline efficiently coupled unit, and the A_{large} refers to the larger organic single-crystalline thin film in the two layers. Preferably, R≥60%; preferably, R≥70%; preferably, R≥80%; preferably, R≥90%; Most preferably, R=100%. The lamination refers to superimposing/stacking organic single-crystalline thin films together to form a laminated structure. For example, the lamination between two layers could result in bilayer structure, as shown in FIG. 3B.

The synergistic growth refers to the precise control over the growth rate, growth interface or other aspects in the organic single-crystalline heterojunction with different organic molecules, in order to realize the growth of different organic single-crystalline thin films without interfering with each other, hence an organic single-crystalline heterojunction with highly efficient lamination could be achieved. Specifically, the synergistic growth means that the growth directions of the crystal C_{T} (which is in the organic single-crystalline thin film M_{T}) and the crystal C_{B} (which is in the organic single-crystalline thin film M_{B}) are basically the same, for ensuring that the C_{T} in the second layer can be laminated on the C_{B} in the first layer over the largest area, thereby the maxim the lamination area ratio could be achieved for promoting the highly efficient lamination of organic single-crystalline efficiently coupled unit.

In some embodiments, the laminating coupled growth method refers to the application of shearing to the mixed solution for obtaining an organic single-crystalline efficiently coupled unit; the mixed solution refers to a solution in which two or more solutes are simultaneously dissolved; one of the solutes aforementioned is selected from organic semiconductor molecules; the two or more solutes above-mentioned have a common solvent, and the common solvent refers to a solvent in which the two or more solutes are dissolved at the same time; the common solvent may include one or more solvents; the solubility (S) of the two or more solutes in a common solvent is ≥0.05 wt % (S≥0.05 wt %); there is no mutual reaction and co-crystal formation between the different types of solutes. The two or more solutes could realize horizontal phase separation (unequal velocity phase separation) and/or vertical phase separation (different interface phase separation) during the crystal growth process. The unequal velocity phase separation means that the crystal growth rate between different solutes is not completely equal, and the different interface phase separation means that the growth interface between different solutes is not completely the same. The growth interface above-mentioned refers to the interface that initiates the nucleation and growth of crystals in the growing process. The growth interface is selected from air-liquid interface and solid-liquid interface. Preferably, the solubility S≥0.1 wt %; preferably, the solubility S≥0.2 wt %; preferably, the solubility S≥0.3 wt %; preferably, the solubility S≥0.4 wt %; preferably, the solubility S≥0.5 wt %. The solubility is the mass percentage of the solutes (which are dissolved in the solvent) to the solution.

The introduction of the applied shearing force has a guiding effect on the growth front of the organic single crystals in the solution, forcing the organic molecules to grow along the direction of the applied shearing force, so as to achieve the laminating coupled growth method for the uniformly oriented organic single crystals. The organic single-crystalline heterojunction composite film grown by the laminating coupled growth method exhibits uniform orientation. Therefore, compared with films displaying intersecting, branching, or disorderly oriented morphology, the carrier trapping by defects/grain boundaries is avoided in the organic single-crystalline heterojunction composite film, which ensures the high-quality charge transport and improvement on the electrical/optoelectrical properties of related semiconductor devices. Moreover, the uniform orientation of the heterojunction film greatly reduces the inhomogeneity in the subsequent device preparation. Furthermore, the electrodes can be prepared directly according to the orientation direction of the organic single-crystalline heterojunction composite film, finally a highly integrated and uniform array of devices with multiple functions could be obtained.

It should be noted that two or more solutes are fully dissolved in a common solvent to prepare a mixed solution, in order to guarantee that the organic single-crystalline heterojunction composite film can be directly grown by the one-step method, and the damage to the already grown organic single-crystalline thin film in the process of using other methods (such as mechanical transfer method, orthogonal solvent method and so on) could be avoided. For many soluble organic semiconductor small molecules which have been successfully synthesized, especially for those who have similar solubility, applying a common solvent to dissolve two or more solutes is a perfect choice, which extends the range for material selection in the preparation of organic single-crystalline heterojunction composite films using solution method. This method can allow two or more solutes to be fully dissolved in a common solvent, and the full dissolution includes a post-processing step for the mixed solution. For example, the post-processing step could contain any one or more of heating, stirring, and sonication, so as to ensure enough mass transportation to the crystal growth front during the solvent evaporation and provide sufficient supply for the continuous crystal growth, eventually high coverage in the two dimensions (including the direction V and the direction H) will be obtained.

No mutual reaction and co-crystal formation between the different types of solutes aforementioned could prevent single-crystalline thin film suffering from two aspects as follows: first, the mutual reaction occurred between solutes leading to the inability of forming thin films; second, the formation of solid solution crystals or co-crystals will destroy the single-crystalline morphology, causing failure of single-crystal growth. In order to ensure that two or more solutes do not interfere or affect each other when they grow in the mixed solution, the growth rate and/or growth interface of the two or more solutes in the solution are different. Different growth rates guarantee that the nucleation and growth of organic single crystals could realize horizontal phase separation (unequal velocity phase separation). The post-deposited organic single crystals can grow along the “template” formed by the pre-deposited organic single crystals, in order to obtain a laminated organic single-crystalline heterojunction composite film. The detection method of horizontal phase separation can be determined by dynamic capturing (for example, capturing with an optical microscope) and observing the position of the crystal growth fronts of different solutes in the same environment (the shearing temperature, shearing rate, and solvent are the same) to determine the crystallization rate. In the same time period, the earlier the growth front appears, the faster the crystallization rate. During the crystallization process of solution method, with the solvent evaporation, at the three-phase interface (air-liquid-solid interface), solutes will precipitate and initiate for crystal nucleation and growing. The growth interface could be classified into two categories according to the growth tendency of the crystals. One growth mode is considered as having the air-liquid interface that crystals tend to grow at the air-liquid interface, the other growth mode is considered as having the solid-liquid interface that crystals tend to grow at the solid-liquid interface. Solutes with different growth modes (or growth interfaces) could realize vertical phase separation in the direction perpendicular to the substrate through different growth modes by separating interfaces in the mixed solution. That is, a part of the solutes nucleate and grow at the bottom of the droplet (solid-liquid interface), and the other part of the solutes nucleate and grow at the top of the droplet (air-liquid interface) simultaneously. Finally, without interfering with each other, a large-area high-coverage organic single-crystalline heterojunction composite film with highly efficient lamination can be obtained.

When the number of solute types simultaneously existing in the common solvent (P) is greater than or equal to 2 (P≥2), in addition to selection from organic semiconductor materials, (P−2) types of solutes can be selected from assistant agents for modifying crystal growth and/or optoelectrical properties; preferably, the solutes could be selected from dopants, dyes or gels.

In some embodiments, the type of the growth interface (or growth mode) is determined by observing whether the morphology of the organic single-crystalline thin film show a significant change after crossing the obstacles (nanowires deposited on the substrate). Preferably, the detection method for determining the type of the growth interface is: randomly selecting 2p+1 crystals that cross the obstacles along the crystal growth direction, and p is a positive integer greater than or equal to 1, |Ao|≤45°, Ao represents the included angle between the obstacle which meet the selected crystal aforementioned and the direction perpendicular to the crystal growth direction. The difference between the average thickness of the obstacles (h̅ₒ) and the average thickness of the crystals (h̅) is less than or equal to 20 nm, that is, |h̅ₒ−h̅|≤20 nm. If there is no significant morphology change for p+1 crystals after crossing the obstacles, the growth interface could be considered as the air-liquid interface. And if the morphology of p+1 crystals change significantly after crossing the obstacles, the growth interface is the solid-liquid interface. Preferably, |Ao|≤40°; preferably, |Ao|≤30°; preferably, |Ao|≤20°, preferably, |Ao|≤10°; more preferably, |Ao|=0°. The average thickness of the obstacles is the average diameter of the nanowires.

It should be noted that in the growth interface classification method, the morphology of the organic single-crystalline thin film before/after crossing the obstacles pre-deposited on the substrate can be characterized by instruments which could observe the fine structure, such as optical microscope (OM), atomic force microscope (AFM), scanning electron microscope (SEM). The angle Ao is between the selected obstacle and the direction perpendicular to the crystal growth, the absolute value of Ao is ≤45° (|Ao|≤45°), as shown in FIG. 6B. The angle Ao in a specific range can ensure that the nanowire acts as an obstacle in the growing process of crystals. If |Ao|=0°, the nanowire is completely perpendicular to the direction of crystal growth, playing the role of the barrier to help clearly identify the growth interface of crystals. If |Ao|≥45°, the solutes tend to grow along the direction of the nanowires during the crystallization and nucleation, thereby, the nanowires will only cause sight change in the direction of crystal growth due to the failure to act as the hindrance. The type of growth interface can be identified according to the number of the crystals showing no significant change in morphology after crossing the obstacles. If the morphology of more than half of the crystals does not change significantly after crossing the obstacles, it means that the crystal growth occurs at the top interface of the droplet, that is, the growth mode is having an air-liquid interface. Through growing at the air-liquid interface, crystals with complete morphology could be achieved, as the solvent evaporates, the crystals will fall on top of the obstacles ultimately, and the complete morphology of crystals could be maintained, as show in the FIG. 7. If the morphology of more than half of the crystals changes significantly after crossing the obstacles, as shown in FIG. 8, it shows that the crystals grow along the solid-liquid interface. During the growth process, the growth front of the crystals is hindered by the obstacles (the nanowires have equivalent thickness to that of crystals), and the mass transport of solutes is cut off, thereby the crystals cannot stride over the obstacles to ensure the continuous growth for realizing complete morphology. In some cases, only part of the solutes can continue to crystalize, resulting in a significant change in the crystal morphology after crossing the obstacles, which can be considered as the growth mode having a solid-liquid interface. The change of the crystal morphology can refer to the change of any one of the crystal growth parameters for each crystals constituting the organic single crystal array, such as the crystal growth direction, crystal width, crystal shape, and so on. By chosing appriorate growth interface and/or coordinating with different growth rates, the nucleation and crystal growth of multi-component solutes can be effectively separated to avoid mutual interference, finally, laminating coupled growth could be achieved. Preferably, the nanowire (obstacle) is selected from inert metals such as silver and gold to avoid possible corrosion caused by solvents. Preferably, the nanowire (obstacle) on the substrate can be prepared by spin coating a suspension containing the nanowire. For optical microscope detection, the area of crystals and obstacles can be clearly observed under the optical microscope at an appropriate magnification, the magnification could be at tens of/hundreds of times to observe the morphology change of the crystals after crossing the nanowire. As shown in FIG. 7 (at 100× magnification), the crystal morphology is basically unchanged before and after crossing the nanowire, which indicated that the growth interface is the air-liquid interface. As shown in FIG. 8 (at 100× magnification), the morphology of the crystals has changed significantly after encountering nanowire, the suddenly narrowed crystal width and even the discontinuous crystal growth have been displayed, indicating the change of the morphology, it can be considered that the crystal grows along the substrate, and the growth interface is the solid-liquid interface. The morphology of the organic single-crystalline thin film specifically refers to the crystal morphology in the organic single-crystalline thin film constructed by the single crystals. The significant change in the morphology of the crystals means that the crystal morphology after crossing the obstacles has any one or more changes in orientation, branching, bending, and deformation. For example, as shown in FIG. 8, the deformation has been showed in the crystal morphology.

The growth environment of the same crystals can be regulated in order to realize the manipulation of the growth interface. The regulation of the growth environment refers to the regulation of environmental factors that affect the way of crystal nucleating during the crystal growth. By regulating the solvent-solvent interaction, the solvent-solute interaction, the solute-substrate interaction, or the solvent-substrate interaction, the control of crystal growth can be realized. The substrate also includes the modification layer on the substrate for the modified substrate. Moreover, the specific measures for control include any one or more of the types of solvent and/or the ratio of mixed solvents, the type of modification layer on the substrate, the shearing temperature, as well as the shearing speed. For example, by choosing different type of solvent, the growth interface of the same type of crystals could be changed. When the organic solution is prepared with toluene as the solvent, the crystal morphology is basically unchanged after the encounter with the obstacles (as shown in FIG. 7), the growth interface is the air-liquid interface. However, if the solvent is replaced by heptane, the surface tension of the solvent has been changed, and the solvent is easier to evaporate since heptane has a lower boiling point compared with toluene. In addition, the molecular structure of heptane comprises long-chain alkanes instead of the π-conjugated structure in the molecular structure of toluene, thereby, the solvent-solvent interaction, the solvent-solute interaction, and the solvent-substrate interaction could be altered. As a result, after meeting the obstacle, the crystal morphology has undergone a huge change, even hindering the continuous growth of crystals. The growth interface becomes a solid-liquid interface, and the way of nucleation for the crystals has changed from the homogeneous nucleation to heterogeneous nucleation. Thus, the nucleation density and subsequent growth are affected by the surface morphology of the substrate. Ultimately, the crystal growth crossing the obstacle will be disturbed when encountering the nanowires with an average diameter equal to the thickness of the crystal, which even hinders the mass transport of the solutes, and the discontinuity of the crystal appears (as shown in FIG. 8).

In some embodiments, the method for preparing the organic single-crystalline efficiently coupled unit includes the following steps:

(1) preparing a mixed solution with two or more solutes that can achieve horizontal phase separation and/or vertical phase separation, dissolving two or more solutes with a common solvent to control the solutes to realize laminating coupled growth in the mixed solution;

(2) regulating the ambient temperature and ambient humidity of the growth environment to obtain a stable growth environment. During the crystal growth process, the deviation of the ambient temperature is ≤+2° C., and the deviation of the ambient humidity is ≤±3%; preferably, the range of ambient temperature is selected from 10° C. to 35° C.; preferably, the range of ambient temperature is selected from 15° C. to 30° C.; preferably, the ambient humidity is ≤55%; preferably, the ambient humidity is ≤50%; preferably, the ambient humidity is ≤45%; more preferably, the ambient humidity is ≤40%;

(3) adjusting the distance between the shearing tool and the substrate to obtain a solution storage space; the solution storage space is the space formed between the substrate and the lower surface of the shearing tool; the space distance is 50 μm to 300 μm; the deviation of the distance between the substrate and the lower surface of the shearing tool is ≤10 μm; preferably, the distance between the shearing tool and the substrate is 100 μm to 150 μm; preferably, the lower surface of the shearing tool is basically parallel to the substrate;

(4) filling the mixed solution prepared in step (1) into the solution storage space in step (3), and resting the solution for 1 s to 30 s after filling;

(5) using a shearing tool to shear the mixed solution along a constant direction at a constant shearing speed at a constant shearing temperature, in order to obtain the organic single-crystalline efficiently coupled unit; each layer of the organic single-crystalline efficiently coupled unit is an organic single-crystalline thin film; the constant shearing temperature refers to the deviation of the shearing temperature is +1° C. during the shearing process; the shearing temperature is 0° C. to 200° C.; the shearing speed is 10 μm/s to 2000 μm/s; preferably, the ratio of the deviation of the shearing speed to the selected shearing speed is ≤+2%; preferably, the shearing temperature is 20° C. to 150° C.; preferably, the shearing temperature is 30° C. to 100° C.; preferably, the shearing speed is 30 μm/s to 1500 μm/s; preferably, the shearing speed is 50 μm/s to 1000 μm/s.

Specifically, in the step (1), the dissolving ability for selected solutes in the selected solvent should be considered. Preferably, the common solvent for selected multiple solutes should be guaranteed for fully dissolving. Moreover, the influence of the evaporation rate of solvent on the crystal growth and the selection range of the shearing temperature should also be considered. Preferably, organic solvents with a higher boiling point and containing π-conjugated structure are applied to prepare the organic solution. A solvent with a higher boiling point can ensure a wider range of shearing temperature, and the growing process will be less affected by the ambient temperature. On the other hand, π-π interactions might existed between the organic solvents containing π-conjugated structure and small organic semiconductor molecules (which are also composed of π-conjugated structure), which is beneficial to improve the solubility of the selected solutes. More preferably, benzene solvents such as toluene, xylene, trimethylbenzene, chlorobenzene, dichlorobenzene, trichlorobenzene, decalin, tetrahydronaphthalene, and chlorinated naphthalene can be selected. The evaporation rate of the solution during the preparation of the organic semiconductor single-crystalline layer can be controlled by using appropriate solvent, in order to achieve more precise control over the obtained single crystals and the morphology of the organic single-crystalline heterojunction composite film. In addition to a single solvent, multiple solvents can also be mixed to prepare a solution of a multi-solvent system. For example, non-polar alkanes or halogen-containing organic solvents can be mixed with different ratio to realize more sophisticated manipulation for the polarity of the solution, the evaporation rate, and even the dimensions of the crystal morphology. For example, the morphology of fullerene single crystals is different via grown with different solvent: one-dimensional needle-like crystals from m-xylene and one-dimensional ribbon-like crystals from the mixed solvents composed by m-xylene and carbon tetrachloride (CCl₄), thus, the probability of achieving highly efficient lamination between different layers of organic single-crystalline thin films can be increased by adjusting the solvents. In addition, various method could be applied in order to ensure that the selected multi-component solutes could be fully dissolved in the organic solvent. For example, the organic semiconductor molecules can be fully diffused and uniformly distributed in the entire mixed solution by stirring overnight on a hot stage or ultra-sonication with heating. Insufficient dissolution might lead to increased heterogeneous nucleation sites, which will result in the smaller crystalline grains, even more, some insoluble solutes may directly precipitate before crystallization into crystals. On the one hand, it becomes the defect in the organic single-crystalline heterojunction composite film, on the other hand, it seriously impacts the orientation of the crystal growth, reducing the electronic/optoelectrionic performance and the uniformity of related device. By using the methods aforementioned, the insufficient dissolution could be avoided.

The selected multi-component solutes have different growth rates and/or growth interfaces in the mixed solution, in order to ensure achieving the phase separation during the growth process of the one-step method. For solutes with different growth rates, the phase separation is mainly attributed for the different speed of precipitation and nucleation of solutes in a common solvent. Solutes with fast precipitation could nucleate and grow at first, while solutes with slow precipitation nucleate and grow later, therefore horizontal phase separation could be obtained. As for solutes with different growth interfaces, one part of solutes grow at the air-liquid interface, and the other part of solutes grow at the solid-liquid interface, so that the nucleation and growth of crystals occur at different growth interfaces, achieving vertical phase separation. The solutes with horizontal and/or vertical phase separation can nucleate and grow without interfering with each other, which further provides the guarantee for the realization of laminating coupled growth, which is beneficial for obtaining organic single-crystalline heterojunction composite film with the lamination area ratio as large as possible.

In the step (2), the ambient temperature and ambient humidity of the growth environment need to be precisely controlled to obtain a relatively stable growth environment. High ambient humidity usually causes water molecules to be adsorbed on the surface of the substrate. On the one hand, the wettability will be affected when the mixed solution is spread on the substrate, leading to the influence on the nucleation and subsequent growth of solutes. On the other hand, too high ambient humidity could result in water molecules adsorbed on the surface of the grown crystal, which will impact the electrionic/optoelectrionic properties of the organic single-crystalline heterojunction composite film. Especially for charge carrier transport, the absorbed water molecules are easy to become traps capturing electrons, which greatly reduced the n-type mobility, and may even cause device deactivation. Usually, it is difficult to completely remove the moisture, even through treatments like high temperature or high vacuum. In addition, high ambient humidity tends to affect the stability of the obtained organic single-crystalline heterojunction composite film. The ambient temperature of the growth environment will affect the evaporation rate of the solution and the diffusion of the solutes concentration gradient during the solution shearing process. Due to the difference in the coefficient of thermal expansion between the organic single-crystalline thin film and the substrate, excessively high or low ambient temperature will result in cracks in organic single-crystalline thin films, which will also act as defects and hinder the realization of high-performance electrionic/otoelectrionic properties.

In the step (3), in order to provide a suitable solution storage space, it is necessary to precisely control the gap distance between the shearing tool and the substrate. In the solution storage space, the diffusion and exchange of solutes can be realized. Since the solution storage space is located on the heated substrate, the temperature gradient will result in a concentration gradient contributing for the solute diffusion. Excessively large gap distance will rise up the solution storage space, greatly increasing the area exposure to air, thus, the solvent is easier to evaporate, which lead to the influence on the solute diffusion. Insufficient supply to the growth front of the crystals might occur, as a result, the growth of the crystal is no longer continuous, discontinuity and non-uniform thickness will appear in the obtained organic single-crystalline thin film. If the gap distance is too small, the insufficient solution storage space will be gained. On the one hand, the solution volume is not enough, which will reduce the vertical coverage ratio of the organic single-crystalline thin film. On the other hand, the shearing effect from shearing tool is greatly enhanced, influencing the thickness of the organic single-crystalline thin film. Additionally, the vertical space between the solution and the substrate (in the direction perpendicular to the substrate) will be too small, causing spatial confinement in the vertical direction, thereby, insufficient space for the crystallites transforming from a metastable polymorph to an equilibrium polymorph leads to the existence of metastable polymorphs in the final crystalline thin film, eventually, the overall quality of crystalline thin films and heterojunction composite films is decreased. Similarly, non-parallel shearing tool will cause non-uniform solution shearing and hinder the formation of regular morphology of organic single-crystalline thin films. It lowers the total lamination area between the organic single-crystalline thin films of different layers, and reduces the quality of the final organic single-crystalline heterojunction composite films. The deviation of the shearing speed (shearing speed deviation) refers to the difference between the actual values deviating from the set values of the shearing speed during the shearing process. The smaller the shearing speed deviation, the more stable the shearing speed, which is conductive to the well-aligned crystal growth of organic molecules. Similarly, the deviation of the ambient temperature, the deviation of the ambient humidity, the deviation of the shearing temperature, and the deviation of the gap distance also refer to the difference between the actual values and the set values for the parameters respectively.

Preferably, the shearing tool used for solution shearing is selected from the tools which could form a solution storage space with ability of storing certain volume of solution on the substrate, such as knifes, blades, smooth bars, wired bars, brushes, and so on. More preferably, the shearing tool adopts a smooth rod or a wired bar to manipulate the volume of the solution storage space, so as to realize the control of the exposure time of the solution meniscus and growth rate of the organic single-crystalline thin film.

In the step (4), it is necessary to fill the solution storage space with the mixed solution, otherwise the horizontal coverage ratio of the organic single-crystalline thin film will be greatly reduced, and partial area of the organic single-crystalline thin film will be missing. Resting the solution for a period of time is to ensure gaining a suitable density of nucleation sites. Thus, the probability of achieving a highly efficient lamination area ratio between different layers of organic single-crystalline films is increased, so that the organic single-crystalline heterojunction composite film could achieve continuous growth with high coverage. However, if the standing time is too long, the excessive solvent evaporation and early solute precipitation will appear, resulting in uncontrolled crystal morphology.

In the step (5), it is necessary to precisely control the shearing conditions, thereby the shearing tool must meet the “three constants” conditions at the same time when shearing the mixed solution after standing (or resting), that is, shear the mixed solution along a constant direction and at a constant shearing speed at a constant shearing temperature. The solution shearing meeting the “three constant” conditions can maintain a stable environment for the growth process of the organic single-crystalline heterojunction composite film. Because growing organic single-crystalline thin films requires extremely strict conditions, even a very tiny instability will disturb the growth of organic single crystals in the mixed solution, leading to the discontinuous growing of crystals or morphology change, moreover, it is difficult to guarantee the single-crystallinity. Therefore, maintaining a stable environment can minimize the unstable interference, it is beneficial to realize the undisturbed nucleation and crystal growth of each type of solutes in the mixed solution according to their horizontal phase separation or vertical phase separation respectively, obtaining the organic single-crystalline heterojunction composite film with highly efficient lamination. The shearing force in a constant direction could guide the mixed solution to realize the laminating coupled growth, and obtain the laminated organic single-crystalline heterojunction composite film ultimately. The shearing process should be carried out within a suitable range of shearing speed and shearing temperature, and the shearing temperature needs to coordinate with the shearing speed to match the nucleation and growth rate of the crystals. The conditions of shearing temperature and shearing speed can be adjusted according to the actual situation. If the shearing temperature is too low, the evaporation rate of the solvent during solution shearing will be too slow, which is not good for realizing the well-aligned growth of the organic single-crystalline thin film. As a result, the effective charge carrier transport in the organic single-crystalline thin film will be reduced. If the shearing temperature is too high, the solvent evaporation rate will be too fast, it may cause the organic semiconductor molecules to stagnate for too long in the solution storage space formed between the lower surface of the shearing tool and the substrate. The obtained single crystals are inconsistent, the coverage ratio of the organic single crystal film decreases, and at the same time, excessively high shearing temperature will cause the cracks or other forms of damage in the obtained organic single-crystalline thin film, reducing the performance of the organic single-crystalline heterojunction composite film. Similarly, if the shearing speed is too slow, the shearing effect on the solution is insufficient to control the crystal morphology, therefore, the random orientation is prone to appear and result in failure to achieve laminating coupled growth. If the shearing speed is too fast, the shearing effect on the solution will be too strong, and the solution storage space will be dragged away by the shearing tool before the complete growth of crystals, which will cause the crystals to be too thin, moreover, the surface roughness of the crystal increases and the quality of the crystal decreases. It is very possible that an organic single-crystalline heterojunction composite film with a good morphology will not be obtained, and eventually lead to the inability of the subsequent preparation of the device. Therefore, only by applying the solution shearing to the mixed solution in a constant direction under the shearing speed and shearing temperature within the appropriate range, precise control of the thickness, orientation, lamination area ratio and coverage ratio (including the horizontal coverage ratio and the vertical coverage ratio) of the organic single-crystalline heterojunction composite film could be achieved, and the organic single-crystalline heterojunction composite film with an ideal morphology can be obtained.

In some embodiments, the solutes for the preparation method of the organic single-crystalline efficiently coupled unit are selected from any one or more of organic semiconductor molecules, organic molecules with optoelectric properties, and organic molecules with ferroelectric properties.

In some embodiments, organic semiconductor molecules aforementioned in the preparation method of organic single-crystalline efficiently coupled unit aforementioned are selected from any one or more of linear acenes, linear heteroacenes, benzothiophene, perylene, perylene diimides, naphthalene diimides, fullerene, and their respective derivatives. And the derivatives aforementioned contain cyano or halogen substituted compounds. The organic molecules with optoelectric or ferroelectric properties refer to the organic materials those have potential for exhibiting any one or more of optoelectric or ferroelectric behaviors.

The third object of the present disclosure is to provide a method for preparing an organic single-crystalline heterojunction composite film. The preparation method includes the steps of preparing an organic single-crystalline efficiently coupled unit according to any one of the aforementioned methods.

In some embodiments, the preparation method of the organic single-crystalline heterojunction composite film includes overlaying single-layer or multilayer organic single-crystalline thin films prepared by other methods on the one or more organic single-crystalline efficiently coupled units.

In some embodiments, the other methods are selected from any one or more of casting method, solution shearing method, spin coating method, printing method, vapor phase deposition, and mechanical transfer method. The other methods aforementioned refer to the methods other than preparing the organic single-crystalline efficiently coupled unit.

In some embodiments, the method for preparing the organic single-crystalline heterojunction composite film includes a post-treatment step, and the step refers to the post-treatment of the entire organic single-crystalline heterojunction composite films, and/or post-treatment of the organic single-crystalline efficiently coupled units, and/or post-treatment of each layer/multiple layers of organic single-crystalline thin films. Preferably, the post-treatment is selected from any one or more of annealing, vacuum treatment, solvent annealing treatment, or surface treatment; preferably, the surface treatment is selected from any one or more of ultraviolet ozone treatment, plasma treatment, infrared light treatment, or laser etching. The post-treatment refers to a treatment to further improve the morphology and/or performance of the prepared organic single-crystalline thin film by using a physical/chemical method. For example, after annealing, the stability of the organic single-crystalline thin film is improved.

In some embodiments, the fourth object of the present disclosure is to provide an array of optoelectronic devices, the array of optoelectronic devices includes one or more optoelectronic devices integrated in P spatial dimensions, and P is a positive integer greater than or equal to 1. The schematic diagram of the structure is shown in FIG. 9. If P=1, the optoelectronic device array is expanded in one dimension, and the array of optoelectronic devices can be obtained by integrating one or more optoelectronic devices in the x-axis direction. If P=2, the array of optoelectronic devices can be obtained by integrating one or more optoelectronic devices on the xy plane. If P=3, the array of optoelectronic devices can be obtained by integrating one or more optoelectronic devices in the xyz space. The optoelectronic device comprises any type of organic single-crystalline heterojunction composite film aforementioned, and the organic single-crystalline heterojunction composite film prepared by any type of method above-mentioned.

In some embodiments, the optoelectronic device is selected from any one or more of organic thin film transistors, organic solar cells, organic light-emitting diodes, organic complementary circuits, organic sensors and organic memory devices.

The fifth object of the present disclosure is to provide the application of the any type of organic single-crystalline heterojunction composite film aforementioned, and any type of optoelectronic device array aforementioned (the schematic diagram is shown in FIG. 17) in the fields of semiconductor devices, transportation logistics, mining, metallurgy, environment, medical equipment, explosion-proof testing, food, water treatment, pharmaceuticals, and biologicals.

Compared with the existing technology, the beneficial effects of the present disclosure are:

The preparation method provided by the present disclosure overcomes the technical prejudice, turns the preparation of an ideal organic single-crystalline heterojunction composite film into reality. For the first time, the heterojunction interface with high degree of ordering and highly efficient lamination are satisfied simultaneously. And the performance of heterojunction composite film has been greatly improved compared with the current level. On this basis, the organic single-crystalline heterojunction composite film further satisfies the requirement of two-dimensional high coverage of organic single-crystalline thin film. Finally, the organic single-crystalline heterojunction composite film with an ideal morphology that satisfies the above three conditions at the same time is obtained. Morphology with regularity, continuity, uniform orientation and the organic single-crystalline heterojunction interface with highly efficient lamination could be achieved in the organic single-crystalline heterojunction composite film, which is prepared via the method provided by the present disclosure. The organic single-crystalline heterojunction composite film provides an ideal interface for realizing the high-performance electronic/optoelectronic behavior, moreover, it comprises at least one layer of two-dimensional high-coverage organic single-crystalline thin film that could achieve high coverage in both horizontal and vertical directions. In addition, the organic single-crystalline heterojunction composite film could be prepared on a large scale, and the subsequent preparation steps of related optoelectronic devices could be simplified, which facilitates integration and large-scale production for industry.

For organic heterojunction composite film existing as the most ideal material form (organic single-crystalline thin film), the preparation of high-quality organic single-crystalline heterojunction composite film (the requirements of heterojunction interface with high degree of ordering and highly efficient lamination are met at the same time) has already been very difficult. Currently, the realization of the most ideal morphology (the three conditions including heterojunction interface with high degree of ordering, highly-efficient lamination, and two-dimensional high coverage of organic single-crystalline film are met at the same time) is the largest bottleneck. However, during the growth process of the organic single-crystalline heterojunction composite film, the present disclosure overcomes the difficulty that the surface of the pre-prepared first layer of organic single-crystalline thin film is easily to be damaged by the second layer of organic single-crystalline thin film. A high-quality and highly ordered heterojunction interface is obtained by adopting the laminating coupled growth method in the mixed-solution, which provides a high-quality channel for charge carrier transport. In addition, the present disclosure utilizes the tendency of solutes realizing phase separation (horizontal phase separation/vertical phase separation) in the mixed solution, which greatly reduces the mutual interference during the nucleation and crystal growth of multiple solutes in a common solvent. The severely impact of the thickness and the physical/chemical properties of the crystal surface of the first layer of organic single-crystalline thin film is avoided when the second layer of organic single-crystalline thin film is grown, moreover, the interference to the growth direction of crystals is reduced, and the laminated organic single-crystalline heterojunction composite film with the largest possible lamination area is obtained. Thus, the platform for electric/photoelectric behaviors at the heterojunction interface could be fully utilized, which can meet the requirements for the subsequent preparation of high-performance devices. The present disclosure also realizes precise regulation and control over the morphology of the organic single-crystalline thin film, with the prerequisite that the adjacent double layers are all organic single-crystalline thin films, at least one layer of the organic single-crystalline thin film in the organic single-crystalline heterojunction composite film could realize the two-dimensional high coverage, which greatly improves the integration of devices/device arrays.

### BRIEF DESCRIPTION OF THE DRAWINGS

FIG. 1 is the schematic diagram of an organic single-crystalline heterojunction composite film and the organic single-crystalline efficiently coupled unit.

FIGS. 2A-2E are the schematic diagrams of the morphology of the organic single-crystalline heterojunction composite film; wherein FIG. 2A-FIG. 2C are schematic diagrams of the lamination area of organic single-crystalline heterojunction composite films with different morphologies, respectively; FIG. 2A and FIG. 2D are laminated organic single-crystalline heterojunction composite films with uniform orientation; FIG. 2B are organic single-crystalline heterojunction composite film with independently dispersed morphology; FIGS. 2C and 2E are organic single-crystalline heterojunction composite films grown in the staggered mode.

FIGS. 3A-3F are schematic diagrams of different laminating methods between the two organic single crystals in the organic single-crystalline heterojunction composite film, wherein FIG. 3A is cross-stacked, FIG. 3B is bilayer, FIG. 3C is lateral-stacked, FIG. 3D is axial-stacked, FIG. 3E is core-shell stacked, and FIG. 3F is branched.

FIGS. 4A-4I are different laminating methods between the three organic single crystals in the organic single-crystalline heterojunction composite film, respectively, and different colors represent different types of organic single crystals.

FIG. 5 is a schematic diagram of the organic single-crystalline thin film of the present disclosure, l₁, l₂, . . . , 1ₙ represent the length of the 1, 2, . . . , n crystals along the crystal growth direction, respectively, w₁, w₂, . . . , wₙ represent the width of the 1, 2, . . . , n crystals in the direction perpendicular to the crystal growth direction, respectively; L is the length of the substrate, W is the width of the substrate.

FIG. 6A is a schematic diagram of the orientation angle between two layers of organic single crystals in the organic single-crystalline heterojunction composite film of the present disclosure, where A_{L} is the laminated orientation angle; FIG. 6B is a schematic diagram of the included angle between the obstacle and the direction perpendicular to the crystal growth direction in the detection method for growth interface provided by the present disclosure, where Ao is the included angle.

FIG. 7 is an optical microscopic image of organic single-crystalline thin film grown at the air-liquid interface.

FIG. 8 is an optical microscopic image of organic single-crystalline thin film grown at the solid-liquid interface.

FIG. 9 is a schematic diagram of the effect of the integrated array of optoelectronic devices of the present disclosure.

FIGS. 10A-10B are the optical microscopic image and the schematic diagram of the organic single-crystalline heterojunction composite film of Example 1, respectively.

FIGS. 11A-11B are the optical microscopic image and the polarized optical microscopic image of the organic single-crystalline heterojunction composite film of Example 1, respectively.

FIG. 12 is a scanning electron micrograph of the organic single-crystalline heterojunction composite film of Example 1.

FIG. 13 is the typical transfer curve for hole and electron transport under the working voltage of V_{D}=−120V, V_{G}=−120V in the ambipolar organic single-crystalline field-effect transistor, which is based on the organic single-crystalline heterojunction composite film of Example 1.

FIG. 14 is a polarized optical microscopic image of the organic heterojunction film of Comparative Example 3.

FIG. 15 is an optical microscopic image of the organic heterojunction film of Comparative Example 7.

FIG. 16 is an optical microscopic image of the organic heterojunction film of Comparative Example 10.

FIG. 17 is a schematic diagram of the evolution from the organic single-crystalline heterojunction composite film of the present disclosure to the optoelectronic device to the integrated array of optoelectronic devices.

FIGS. 18A-18B are the optical microscopic image in the prior art that presents the morphology of the organic single-crystalline heterojunction, FIG. 18A is equivalent to FIG. 2a of H. Li, C. Fan, and W. Fu, Angewandte Chemie International Edition, 54, 956 (2015), and FIG. 18B is equivalent to FIG. 5e of H. Li and H. Li, Journal of the American Chemical Society, 141, 25 (2019).

### DETAILED DESCRIPTION OF THE EMBODIMENTS

The present disclosure is further described below with reference to the drawings and embodiments. It should be noted that the following embodiments are used to illustrate the present disclosure but not to limit the scope of the present disclosure. In addition, it should be understood that after reading the teachings of the present disclosure, those skilled in the art can make various changes or modifications to the present disclosure, and these equivalent forms also fall within the scope defined by the appended claims of this application.

The terms “upper”, “lower”, “left”, “right”, “vertical”, “parallel”, “inner”, “outer”, “before”, “after”, etc. indicate that the orientation or positional relationship is based on the orientation or positional relationship shown in the attached figures, and is only for the convenience of describing the present disclosure and simplifying the description, rather than indicating or implying that the pointed device or element must have a specific orientation or a specific/positional relationship orientation. The orientation or positional relationship shown in the figures are only for the convenience of describing the present disclosure and simplifying the description, rather than indicating or implying that the devices or elements referred to must have a specific position, or be constructed/operated in a specific direction/position, therefore, it cannot be understood as a limitation of the present disclosure.

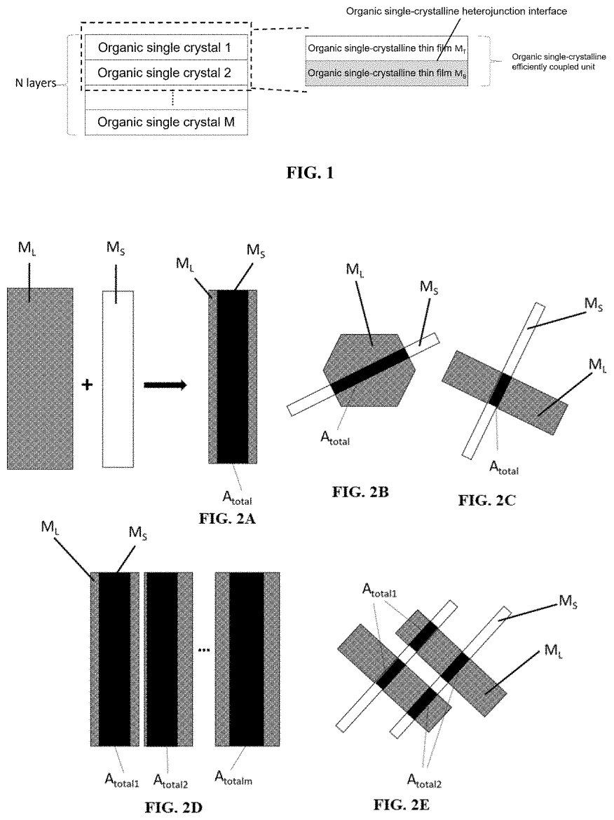

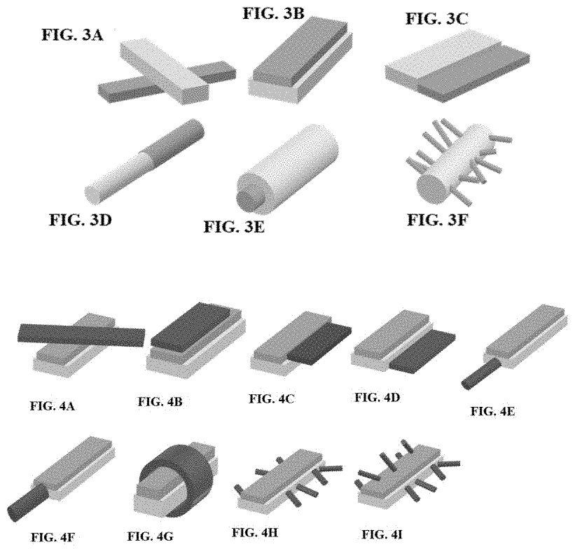

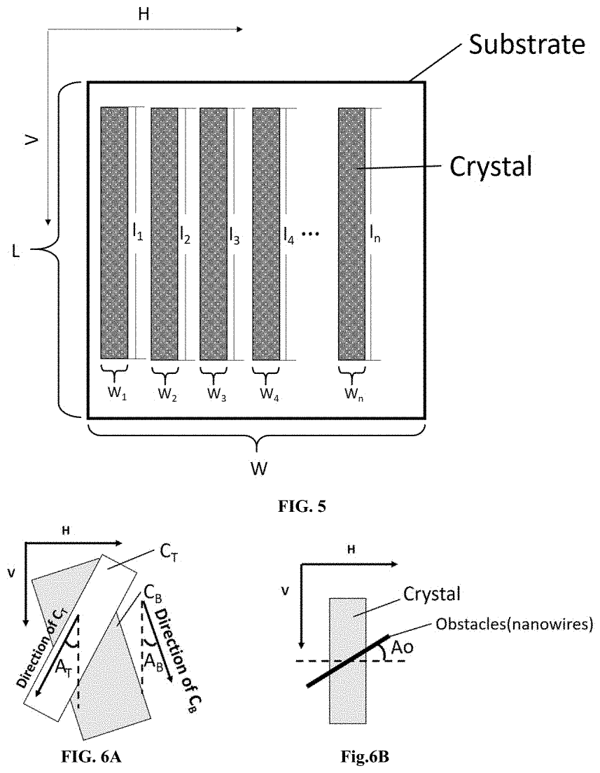

As shown in FIG. 1, the present disclosure provides an organic single-crystalline heterojunction composite film, which comprises M organic materials, and M is a positive integer greater than or equal to 2; the organic single-crystalline heterojunction composite film comprises a laminated structure (laminated construction/configuration/structure), and the laminated structure refers to the organic single-crystalline heterojunction composite film is composed of N layers of organic single-crystalline thin films stacked in sequence, and N is a positive integer greater than or equal to 2; the organic single-crystalline thin film is composed of the organic single crystal array, which is displayed in FIG. 2A, FIG. 2D, FIG. 5, FIGS. 10A-10B and FIGS. 11A-11B, and the organic single crystal array is composed of multiple crystals within single-crystalline state; the organic single-crystalline heterojunction composite film comprises at least one organic single-crystalline efficiently coupled unit; the organic single-crystalline efficiently coupled unit is composed of an organic single-crystalline thin film M_{T} and an organic single-crystalline thin film M_{B}, M_{T} and M_{B} are composed of different materials, additionally M_{T} is located in the upper layer, and the M_{B} is located in the lower layer. The organic single-crystalline efficiently coupled unit has highly efficient lamination, as shown in FIG. 2A, FIG. 2D, FIG. 3B, FIGS. 10A-10B, FIGS. 11A-11B and FIG. 12. A large lamination area ratio and intimate contact between the bilayer organic single-crystalline thin films could be observed in the above-mentioned optical microscopic images, polarized optical microscopic images, scanning electron microscopic images and schematic diagrams, moreover, high-quality organic single-crystalline heterojunction interfaces are formed.

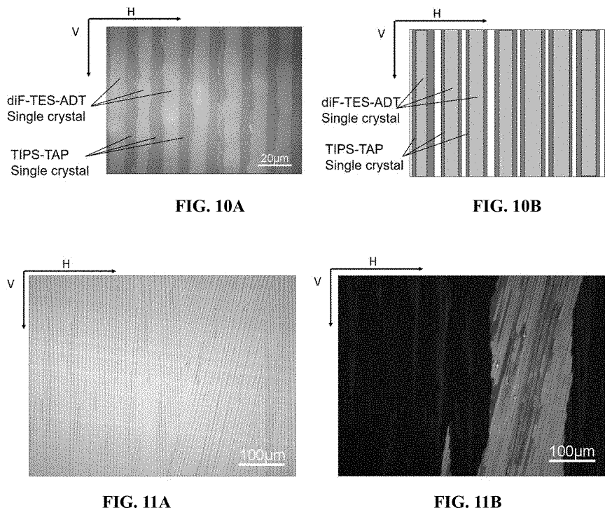

As shown in FIG. 9, the optoelectronic device proposed by the present disclosure can also be integrated in one or more dimensions to obtain an integrated array of optoelectronic devices. The integrated array of optoelectronic devices can be widely used in detectors, inverters, oscillators, backplane for light-emitting diode displays and so on.

The organic single-crystalline thin films can be detected by instruments that could analyze fine structures, such as optical microscope with crossed polarizers, atomic force microscope, scanning electron microscope, transmission electron microscope, laser confocal Raman spectrometer, single-crystal diffractometer, and so on. The type of materials in the organic single-crystalline thin film can be detected by instruments that can analyze the composition of elements, such as scanning electron microscope, transmission electron microscope, laser confocal Raman spectrometer, X-ray diffractometer, infrared spectrometer and so on. The structure and morphology of organic single-crystalline heterojunction composite film and organic single-crystalline efficiently coupled unit can be inspected by optical microscope, atomic force microscope, scanning electron microscope, transmission electron microscope, and so on. The related performance of semiconductor devices can be tested by instruments that can analyze the electrical/optoelectrical performance, such as semiconductor parameter analyzer, Hall effect testing instrument, scanning probe microscope, ferroelectric analyzer, quantum efficiency measurement system, transient spectrometer, solar cell I-V tester, optoelectronic detection system, micro-fluorescence spectrometer, spectrum analyzer, conductance measurement system and so on.

In order to characterize the morphology of organic single-crystalline efficiently coupled unit, an optical microscope was used for observation. To characterize the quality of the organic single-crystalline efficiently coupled unit provided by the present disclosure, field-effect transistors were prepared based on the organic single-crystalline heterojunction composite film containing organic single-crystalline efficiently coupled unit aforementioned, and the field-effect behaviors were tested with a semiconductor parameter analyzer.

### Example 1

An organic single-crystalline heterojunction composite film based on 2,8-difluoro-5,11-bis[2-(triethylsilyl)ethynyl]-anthradithiophene (diF-TES-ADT) and 6,13-bis(triisopropylsilylethynyl)-5,7,12,14-tetraazapentacene (TIPS-TAP), a preparation method for organic field-effect devices based on the composite film, the following steps are included:
(1) providing a heavily doped p-type Si/SiO₂ substrate, wherein the thickness of silicon dioxide insulating layer is 300 nm, then spin-coating the crosslinked polystyrene (c-PS) on the substrate as modification layer;
(2) growing p-type semiconductor molecule diF-TES-ADT and n-type semiconductor molecule TIPS-TAP on a substrate with pre-deposited Ag nanowires (with a diameter about 40 nm) respectively, and observing the morphology change of the organic single-crystalline thin film crossing the electrodes under an optical microscope to determine the growth interface of diF-TES-ADT and TIPS-TAP respectively, dynamic growth process of diF-TES-ADT and TIPS-TAP through the optical microscope to determine their growth rate respectively;
(3) preparing a mixed solution (with total solute mass fraction of 1 wt %) using diF-TES-ADT and TIPS-TAP (1:1) in mesitylene, and stirring the solution on a hot stage at 50° C. for fully dissolving;
(4) regulating the ambient temperature and ambient humidity of the growth environment at 20±1° C. and 50±3%, respectively;
(5) adjusting the gap distance between the shearing tool and the substrate prepared in step (1) to 200±5 μm to form the solution storage space;
(6) filling the mixed solution prepared in step (3) into the solution storage space prepared in step (5), and resting it for 5 seconds after the filling is completed;
(7) using a shearing tool to shear the mixed solution slowly and uniformly in a constant direction at a shearing speed of 400±5 μm/s under a temperature of 60° C. to obtain the bilayer organic single-crystalline heterojunction composite film;
(8) depositing the electrodes of Au by thermal evaporation under a high vacuum to obtain field-effect transistors based the organic single-crystalline heterojunction composite film obtained by step (7).

The substrate can be selected from commonly used organic semiconductor device substrates. Further, the substrate can be a hard substrate, such as a silicon substrate (Si/SiO₂), a metal oxide substrate (AlOₓ) and so on. And the substrate also could be a flexible polymer substrate, such as polyethylene terephthalate (PET), polyethylene naphthalate (PEN), polyimide (PI) and so on. The modification layer on the substrate can be selected from organic polymers or small molecule modification layers that will not be dissolved or corroded by the mixed solution. Preferably, the polymer can be selected from any one or more of polymethyl methacrylate (PMMA) and its cross-linked product (c-PMMA), polyvinyl alcohol (PVA) and its cross-linked product (c-PVA), polyvinyl acetate (PVAc) and its cross-linked product (c-PVAc), polyimide (PI), polyvinylidene fluoride (PVDF), poly(vinylidene fluoride-co-hexafluoropropylene) (P(VDF-HFP)), poly(vinylidene fluoride-trifluoroethylene-chlorofluoroethylene) (P(VDF-TrFE-CFE)), polystyrene (PS) and its cross-linked products (c-PS), poly-α-methylstyrene (PαMS), polyvinylphenol (PVP) and its cross-linked products (c-PVP), parylene, divinyltetramethyldisiloxane-bis(benzocyclobutene) (BCB), perfluoro (1-butenyl vinyl ether) polymer (CYTOP), and cyanoethylpullulane (CYEP), if the polymers selected are more than two types, the modification layer could be prepared by two/more layers mixing/stacking together.

Use optical microscope and atomic force microscope to extract the fine structure and morphology information to characterize the structure and morphology of the obtained organic single-crystalline semiconductor thin films, and the electrical performance of field-effect transistors is characterized by semiconductor parameter analyzer which is capable of detecting the comprehensive electrical properties of various semiconductor devices and materials.

### Example 2

An organic single-crystalline heterojunction composite film based on 2,8-difluoro-5,11-bis[2-(triethylsilyl)ethynyl]-anthradithiophene (diF-TES-ADT) and 6,13-bis(triisopropylsilylethynyl)-5,7,12,14-tetraazapentacene (TIPS-TAP), a preparation method for organic field-effect devices based on the composite film.

For the preparation method of the field-effect transistor device of the Example 2, referring to the Example 1, the formula and process parameters are shown in Table 1 and Table 2, respectively. The structure, morphology and performance characterization methods are the same as those in Example 1. The morphological parameters of the obtained organic single-crystalline heterojunction are shown in Table 3. The related device performance is shown in Table 4.

### Example 3

An organic single-crystalline heterojunction composite film based on diF-TES-ADT and TIPS-TAP, a preparation method for organic field-effect devices based on the composite film.

For the preparation method of the field-effect transistor device of the Example 3, referring to the Example 1, the formula and process parameters are shown in Table 1 and Table 2, respectively. The structure, morphology and performance characterization methods are the same as those in Example 1. The morphological parameters of the obtained organic single-crystalline heterojunction are shown in Table 3. The related device performance is shown in Table 4.

### Example 4

An organic single-crystalline heterojunction composite film based on diF-TES-ADT and TIPS-TAP, a preparation method for organic field-effect devices based on the composite film.

For the preparation method of the field-effect transistor device of the Example 4, referring to the Example 1, the formula and process parameters are shown in Table 1 and Table 2, respectively. The structure, morphology and performance characterization methods are the same as those in Example 1. The morphological parameters of the obtained organic single-crystalline heterojunction are shown in Table 3. The related device performance is shown in Table 4.

### Example 5

An organic single-crystalline heterojunction composite film based on diF-TES-ADT and TIPS-TAP, a preparation method for organic field-effect devices based on the composite film.

For the preparation method of the field-effect transistor device of the Example 5, referring to the Example 1, the formula and process parameters are shown in Table 1 and Table 2, respectively. The structure, morphology and performance characterization methods are the same as those in Example 1. The morphological parameters of the obtained organic single-crystalline heterojunction are shown in Table 3. The related device performance is shown in Table 4.

### Example 6

An organic single-crystalline heterojunction composite film based on diF-TES-ADT and TIPS-TAP, a preparation method for organic field-effect devices based on the composite film.

For the preparation method of the field-effect transistor device of the Example 6, referring to the Example 1, the formula and process parameters are shown in Table 1 and Table 2, respectively. The structure, morphology and performance characterization methods are the same as those in Example 1. The morphological parameters of the obtained organic single-crystalline heterojunction are shown in Table 3. The related device performance is shown in Table 4.

### Example 7

An organic single-crystalline heterojunction composite film based on 6,13-bis(triisopropylsilylethynyl) pentacene (TIPS-PEN) and 2,7-dioctyl[1]benzothieno[3,2-b]benzothiophene (C₈-BTBT) with a preparation method for the composite film.

For the preparation method of the composite film of the Example 7, referring to the step (1-7) in Example 1, the formula and process parameters are shown in Table 1 and Table 2, respectively. The structure and morphology characterization methods are the same as those in Example 1. The morphological parameters of the obtained organic single-crystalline heterojunction are shown in Table 3.

### Example 8

An organic single-crystalline heterojunction composite film based on TIPS-PEN and C₈-BTBT with a preparation method for the composite film.

For the preparation method of the composite film of the Example 8, referring to the step (1-7) in Example 1, the formula and process parameters are shown in Table 1 and Table 2, respectively. The structure and morphology characterization methods are the same as those in Example 1. The morphological parameters of the obtained organic single-crystalline heterojunction are shown in Table 3.

### Example 9

An organic single-crystalline heterojunction composite film based on Perylene and TIPS-TAP, a preparation method for organic field-effect devices based on the composite film.

For the preparation method of the field-effect transistor device of the Example 9, referring to the Example 1, the formula and process parameters are shown in Table 1 and Table 2, respectively. The structure, morphology and performance characterization methods are the same as those in Example 1. The morphological parameters of the obtained organic single-crystalline heterojunction are shown in Table 3. The related device performance is shown in Table 4.

### Example 10

An organic single-crystalline heterojunction composite film based on Perylene and TIPS-TAP, a preparation method for organic field-effect devices based on the composite film.

For the preparation method of the field-effect transistor device of the Example 10, referring to the Example 1, the formula and process parameters are shown in Table 1 and Table 2, respectively. The structure, morphology and performance characterization methods are the same as those in Example 1. The morphological parameters of the obtained organic single-crystalline heterojunction are shown in Table 3. The related device performance is shown in Table 4.

### Example 11

An organic single-crystalline heterojunction composite film based on TIPS-PEN and 9,10-diphenylanthracene (9,10-DPA) with a preparation method for the composite film.

For the preparation method of the composite film of the Example 11, referring to the step (1-7) in Example 1, the formula and process parameters are shown in Table 1 and Table 2, respectively. The structure and morphology characterization methods are the same as those in Example 1. The morphological parameters of the obtained organic single-crystalline heterojunction are shown in Table 3.

### Example 12

An organic single-crystalline heterojunction composite film based on TIPS-PEN and 9,10-diphenylanthracene (9,10-DPA) with a preparation method for the composite film.

For the preparation method of the composite film of the Example 12, referring to the step (1-7) in Example 1, the formula and process parameters are shown in Table 1 and Table 2, respectively. The structure and morphology characterization methods are the same as those in Example 1. The morphological parameters of the obtained organic single-crystalline heterojunction are shown in Table 3.

### Example 13

An organic single-crystalline heterojunction composite film based on Tetracene and TIPS-TAP with a preparation method for the composite film.

For the preparation method of the composite film of the Example 13, referring to the step (1-7) in Example 1, the formula and process parameters are shown in Table 1 and Table 2, respectively. The structure and morphology characterization methods are the same as those in Example 1. The morphological parameters of the obtained organic single-crystalline heterojunction are shown in Table 3.

### Example 14

An organic single-crystalline heterojunction composite film based on Tetracene and TIPS-TAP with a preparation method for the composite film.

For the preparation method of the composite film of the Example 14, referring to the step (1-7) in Example 1, the formula and process parameters are shown in Table 1 and Table 2, respectively. The structure and morphology characterization methods are the same as those in Example 1. The morphological parameters of the obtained organic single-crystalline heterojunction are shown in Table 3.

### Example 15

An organic single-crystalline heterojunction composite film based on 2,6-diphenylbisthieno[3,2-b:2′,3′-d]thiophene (DP-DTT) and TIPS-TAP with a preparation method for the composite film.

For the preparation method of the composite film of the Example 15, referring to the step (1-7) in Example 1, the formula and process parameters are shown in Table 1 and Table 2, respectively. The structure and morphology characterization methods are the same as those in Example 1. The morphological parameters of the obtained organic single-crystalline heterojunction are shown in Table 3.

### Example 16

An organic single-crystalline heterojunction composite film based on Rubrene and Fullerene (C₆₀) with a preparation method for the composite film.

For the preparation method of the composite film of the Example 16, referring to the step (1-7) in Example 1, the formula and process parameters are shown in Table 1 and Table 2, respectively. The structure and morphology characterization methods are the same as those in Example 1. The morphological parameters of the obtained organic single-crystalline heterojunction are shown in Table 3.

### Example 17

A multiple layer organic single-crystalline heterojunction composite film based on Rubrene, C₆₀ and TIPS-PEN, the following steps are included:
(1) providing a heavily doped p-type Si/SiO₂ substrate, wherein the thickness of silicon dioxide insulating layer is 300 nm, then spin-coating the crosslinked polystyrene on the substrate as modification layer;
(2) preparing a mixed solution (with total solute mass fraction of 0.2 wt %) using Rubrene and C₆₀ in chlorobenzene, then preparing a 0.1 wt % TIPS-PEN solution in 4-methyl-2-pentanone separately, and stirring the two solutions on a hot stage at 50° C. for fully dissolving;
(3) regulating the ambient temperature and ambient humidity of the growth environment at 20±1° C. and 50±3%, respectively;
(4) adjusting the gap distance between the shearing tool and the substrate prepared in step (1) to 200±5 μm to form the solution storage space;
(5) filling the mixed solution prepared in step (2) into the solution storage space prepared in step (4), and resting it for 5 seconds after the filling is completed;
(6) using a shearing tool to shear the mixed solution slowly and uniformly in a constant direction at a linear velocity of 400±5 μm/s under a temperature of 60° C. to obtain the bilayer organic single-crystalline heterojunction composite film;
(7) using a shearing tool to shear the TIPS-PEN solution slowly and uniformly on the bilayer composite film prepared in step (6) in a constant direction at a linear velocity of 200±1 μm/s under a temperature of 30° C. to obtain the triple layer organic single-crystalline heterojunction composite film.

The structure and morphology characterization methods are the same as those in Example 1. The morphological parameters of the obtained organic single-crystalline heterojunction are shown in Table 3.

### Comparative Example 1

An organic single-crystalline heterojunction composite film based on Perylene and TIPS-TAP, a preparation method for organic field-effect devices based on the composite film, the following steps are included:
(1) providing a heavily doped p-type Si/SiO₂ substrate, wherein the thickness of silicon dioxide insulating layer is 300 nm, then spin-coating the crosslinked polystyrene on the substrate as modification layer;
(2) preparing a 0.5 wt % TIPS-TAP solution in mesitylene, and stirring the solution on a hot stage at 50° C. for fully dissolving;
(3) regulating the ambient temperature and ambient humidity of the growth environment at 20±1° C. and 50±3%, respectively;
(4) adjusting the gap distance between the shearing tool and the substrate prepared in step (1) to 200±5 μm to form the solution storage space;
(5) filling the mixed solution prepared in step (2) into the solution storage space prepared in step (4), and resting it for 5 seconds after the filling is completed;
(6) using a shearing tool to shear the TIPS-TAP solution slowly and uniformly in a constant direction at a linear velocity of 400±5 μm/s under a temperature of 60° C. to obtain the organic single-crystalline thin film;
(7) depositing the polycrystalline perylene thin film via thermal evaporation on the TIPS-TAP single-crystalline thin film;
(8) depositing the Au electrodes by thermal evaporation under a high vacuum to obtain field-effect transistors based the organic single-crystalline & polycrystalline heterojunction obtained by step (7).

The performance characterization methods are the same as those in Example 1. The related device performance is shown in Table 4. The perylene thin film can be judged as an organic polycrystalline film by observing through an optical microscope.

### Comparative Example 2

An organic single-crystalline heterojunction composite film based on Perylene and TIPS-TAP, a preparation method for organic field-effect devices based on the composite film, the following steps are included:
(1) providing a heavily doped p-type Si/SiO₂ substrate, wherein the thickness of silicon dioxide insulating layer is 300 nm, then spin-coating the crosslinked polystyrene on the substrate as modification layer;
(2) preparing a 0.5 wt % TIPS-TAP solution in toluene, and stirring the solution on a hot stage at 50° C. for fully dissolving;
(3) regulating the ambient temperature and ambient humidity of the growth environment at 20±1° C. and 50±3%, respectively;
(4) spin-coating the TIPS-TAP solution on the substrate to obtain the TIPS-TAP organic polycrystalline thin film;
(5) depositing the polycrystalline perylene thin film via thermal evaporation on the TIPS-TAP polycrystalline thin film;
(6) depositing the Au electrodes by thermal evaporation under a high vacuum to obtain field-effect transistors based the organic polycrystalline & polycrystalline heterojunction obtained by step (5).

The performance characterization methods are the same as those in Example 1. The related device performance is shown in Table 4. Similarly, the perylene thin film and TIPS-TAP thin film can be judged as organic polycrystalline thin films by observing through an optical microscope.

### Comparative Example 3

An organic single-crystalline heterojunction composite film based on diF-TES-ADT and TIPS-TAP, a preparation method for organic field-effect devices based on the composite film.

For the preparation method of the composite film of the Comparative Example 3, referring to the steps in Example 1, the formula and process parameters are shown in Table 1 and Table 2, respectively. The structure and morphology characterization methods are the same as those in Example 1.

### Comparative Example 4

An organic single-crystalline heterojunction composite film based on diF-TES-ADT and TIPS-TAP, a preparation method for organic field-effect devices based on the composite film, the following steps are included:
(1) providing a heavily doped p-type Si/SiO₂ substrate, wherein the thickness of silicon dioxide insulating layer is 300 nm, then spin-coat the crosslinked polystyrene on the substrate as modification layer;
(2) preparing a mixed solution (with total solute mass fraction of 1 wt %) using diF-TES-ADT and TIPS-TAP (1:1) in 1-butanol, filter out the undissolved particles after 30 minutes of ultra-sonication;
(3) regulating the ambient temperature and ambient humidity of the growth environment at 20±1° C. and 50±3%, respectively;
(4) adjusting the gap distance between the shearing tool and the substrate prepared in step (1) to 200±5 μm to form the solution storage space;
(5) filling the mixed solution prepared in step (2) into the solution storage space prepared in step (4), and resting it for 5 seconds after the filling is completed;
(6) using a shearing tool to shear the mixed solution slowly and uniformly in a constant direction at a linear velocity of 400±5 μm/s under a temperature of 60° C. to obtain the bilayer organic single-crystalline heterojunction composite film;
(7) depositing the Au electrodes by thermal evaporation under a high vacuum to obtain field-effect transistors based the organic single-crystalline heterojunction composite film obtained by step (6).

The structure, morphology and performance characterization methods are the same as those in Example 1. The related device performance is shown in Table 4.

### Comparative Example 5

An organic single-crystalline heterojunction composite film based on diF-TES-ADT and TIPS-TAP with a preparation method for the composite film.

For the preparation method of the composite film of the Comparative Example 5, referring to the step (1-7) in Example 1, the formula and process parameters are shown in Table 1 and Table 2, respectively. The structure and morphology characterization methods are the same as those in Example 1. The morphological parameters of the obtained organic single-crystalline heterojunction are shown in Table 3.

### Comparative Example 6

An organic single-crystalline heterojunction composite film based on diF-TES-ADT and TIPS-TAP with a preparation method for the composite film.

For the preparation method of the composite film of the Comparative Example 6, referring to the step (1-7) in Example 1, the formula and process parameters are shown in Table 1 and Table 2, respectively. The structure and morphology characterization methods are the same as those in Example 1. The morphological parameters of the obtained organic single-crystalline heterojunction are shown in Table 3.

### Comparative Example 7

An organic single-crystalline heterojunction composite film based on diF-TES-ADT and TIPS-TAP, a preparation method for organic field-effect devices based on the composite film.

For the preparation method of the composite film of the Comparative Example 7, referring to the step (1-7) in Example 1, the formula and process parameters are shown in Table 1 and Table 2, respectively. The structure and morphology characterization methods are the same as those in Example 1. The morphological parameters of the obtained organic single-crystalline heterojunction are shown in Table 3. The related device performance is shown in Table 4.

### Comparative Example 8

An organic single-crystalline heterojunction composite film based on diF-TES-ADT and TIPS-TAP, a preparation method for organic field-effect devices based on the composite film, the following steps are included:
(1) providing a heavily doped p-type Si/SiO₂ substrate, wherein the thickness of silicon dioxide insulating layer is 300 nm, then spin-coat the crosslinked polystyrene on the substrate as modification layer;
(2) preparing a 0.5 wt % diF-TES-ADT solution in toluene and 0.5 wt % TIPS-TAP solution in toluene solution separately;
(3) regulating the ambient temperature and ambient humidity of the growth environment at 20±1° C. and 50±3%, respectively;
(4) adjusting the gap distance between the shearing tool and the substrate prepared in step (1) to 200±5 μm to form the solution storage space;
(5) filling the TIPS-TAP solution prepared in step (2) into the solution storage space prepared in step (4), and resting it for 5 seconds after the filling is completed;
(6) using a shearing tool to shear the TIPS-TAP solution slowly and uniformly on the substrate prepared in step (1) in a constant direction at a linear velocity of 400±5 μm/s under a temperature of 60° C. to obtain the TIPS-TAP single-crystalline thin film;
(7) filling the diF-TES-ADT solution prepared in step (2) into the solution storage space prepared in step (4), and resting it for 5 seconds after the filling is completed;
(8) using a shearing tool to shear the diF-TES-ADT solution slowly and uniformly on a PDMS film in a constant direction at a linear velocity of 400±5 μm/s under a temperature of 60° C. to obtain the diF-TES-ADT single-crystalline thin film;
(9) transferring the diF-TES-ADT single-crystalline thin film prepared on the PDMS film onto the TIPS-TAP single-crystalline thin film prepared in step (6);
(10) depositing the Au electrodes by thermal evaporation under a high vacuum to obtain field-effect transistors based the organic single-crystalline heterojunction composite film obtained by step (9).

The structure, morphology and performance characterization methods are the same as those in Example 1. The related device performance is shown in Table 4.

### Comparative Example 9

An organic single-crystalline heterojunction composite film based on diF-TES-ADT and C₆₀, a preparation method for organic field-effect devices based on the composite film, the following steps are included:
(1) providing a heavily doped p-type Si/SiO₂ substrate, wherein the thickness of silicon dioxide insulating layer is 300 nm, then spin-coating the crosslinked polystyrene on the substrate as modification layer;
(2) preparing a 0.1 wt % diF-TES-ADT solution in hexane and 0.5 wt % C₆₀ solution in chlorobenzene solution separately;
(3) regulating the ambient temperature and ambient humidity of the growth environment at 25±1° C. and 40±3%, respectively;
(4) adjusting the gap distance between the shearing tool and the substrate prepared in step (1) to 200±5 μm to form the solution storage space;
(5) filing the C₆₀ solution prepared in step (2) into the solution storage space prepared in step (4), and resting it for 5 seconds after the filling is completed;
(6) using a shearing tool to shear the C₆₀ solution slowly and uniformly on the substrate prepared in step (1) in a constant direction at a linear velocity of 400±5 μm/s under a temperature of 80° C. to obtain the C₆₀ single-crystalline thin film;
(7) filling the diF-TES-ADT solution prepared in step (2) into the solution storage space prepared in step (4), and resting for 5 seconds after the filling is completed;
(8) using a shearing tool to shear the diF-TES-ADT solution slowly and uniformly on the C₆₀ single-crystalline thin film in a constant direction at a linear velocity of 200±5 μm/s under a temperature of 30° C. to obtain the organic single-crystalline heterojunction composite film;
(9) depositing the Au electrodes by thermal evaporation under a high vacuum to obtain field-effect transistors based the organic single-crystalline heterojunction composite film obtained by step (8).

The structure, morphology and performance characterization methods are the same as those in Example 1. The related device performance is shown in Table 4.

### Comparative Example 10

An organic single-crystalline heterojunction composite film based on diF-TES-ADT and TIPS-TAP, a preparation method for organic field-effect devices based on the composite film, the following steps are included:
(1) providing a heavily doped p-type Si/SiO₂ substrate, wherein the thickness of silicon dioxide insulating layer is 300 nm, then spin-coating the crosslinked polystyrene on the substrate as modification layer;
(2) preparing a mixed solution (with total solute mass fraction of 0.1 wt %) using diF-TES-ADT and TIPS-TAP (1:1) in toluene, filtering out the undissolved particles after 30 minutes of ultra-sonication;
(3) using the droplet-pinned crystallization method (DPC) for crystallization, dropping the mixed solution on the substrate (on a hot stage of 40° C.) on which a fixed silicon wafer is placed, wherein a bilayer organic single-crystalline heterojunction is prepared after the solvent is completely evaporated;
(4) depositing the Au electrodes by thermal evaporation under a high vacuum to obtain field-effect transistors based the organic single-crystalline heterojunction composite film obtained by step (3).

The structure, morphology and performance characterization methods are the same as those in Example 1. The related device performance is shown in Table 4.

The morphology of the organic single-crystalline semiconductor layers obtained in Examples 1-17 and Comparative Examples 1-10 were characterized by optical microscope (with crossed-polarizers) and atomic force microscope, and the performance of the related devices were tested by a semiconductor parameter analyzer. Optical microscopy is a simple and effective method for observing the morphology of organic single-crystalline thin films. Organic single crystals are anisotropic due to the highly ordered intrinsic structure with periodical molecular ordering. Under the orthogonal linearly polarized light of optical microscope, the object with anisotropy will exhibit the birefringence behavior. When the crystal growth direction is parallel or perpendicular to the polarization angle, the image can be used to determine whether the crystal axis in the field of view is highly oriented by observing whether uniform color and brightness changes occur. This method could be applied to confirm the single-crystallinity (A. Yamamura et al., Science Advances, 4, eaao5758, (2018)). In the polarized optical microscopic image, if the color or gray scale is non-uniform or the color changes, it indicates that the obtained crystal is not a single crystal. For example, as shown in FIG. 1(a) in the literature report (C. W. Sele et al., Advanced Materials, 21, 4926 (2009)), the non-uniform color/gray-scale and large density of grain boundaries were overserved, which indicated that the obtained organic film is polycrystalline. For another example, as shown in FIG. 2 (d-g) in the literature report (C. Kim et al., ACS Applied Materials Interfaces, 5, 3716, (2013)), the crystallites with nearly rounded shape were displayed in the obtained organic film, the brightness inside crystallites are quite different, showing the Maltese cross phenomenon, indicating that the crystallites are spherulites instead of single crystals. The crystals are single crystals if the color/gray-scale of the crystal is basically uniform. For instance, as shown in FIG. 11B, basically uniform color/gray-scale of each crystal is displayed in the bright area. In the same area, the color/gray-scale between different crystals is basically the same, indicating a typical organic single-crystalline thin film. It should be noted that the large-area bright and dark regions of the crystalline thin film in FIG. 11B do not mean the appearance of polycrystallinity, since the orientation of the molecular long axis in the crystals between different regions are slightly different (K. Sakamoto et al., Applied Physics Letter, 100, 123301, (2012)), the angular difference with the polarization axis of the polarizer results in bright and dark divisions. Through the scanning electron microscope, the structure of the bilayer or multilayer organic single-crystalline heterojunction composite film on the microscopic scale can be observed.

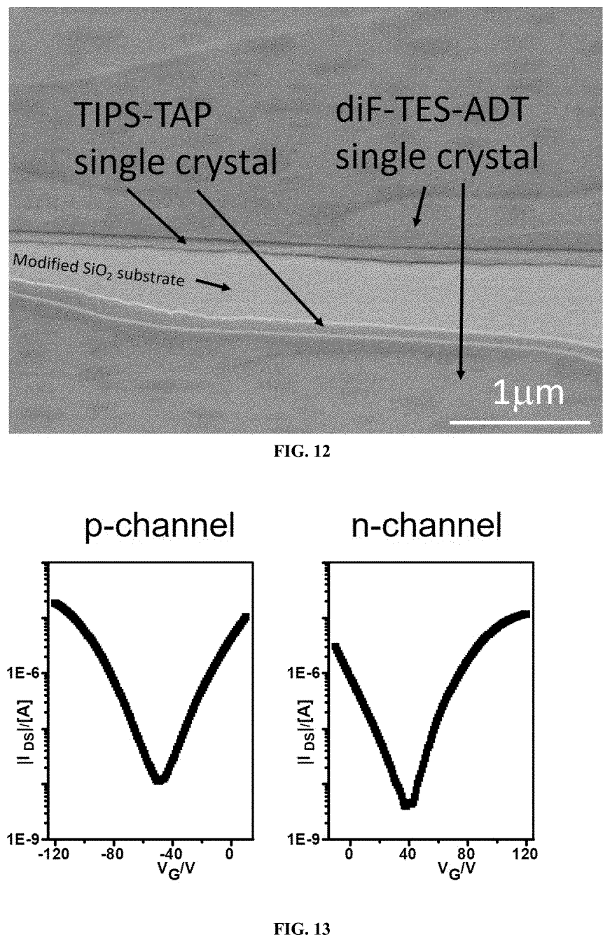

FIG. 10 and FIG. 11 show the morphologies of the organic single-crystalline heterojunction composite film prepared in Example 1. In FIG. 10, a bilayer organic single-crystalline heterojunction composite film with uniform orientation can be seen. The FIG. 10A is the topography observed under an optical microscope at 100× magnification, the thinner strips represent diF-TES-ADT crystals, and the wider strips are TIPS-TAP crystals. The FIG. 10B is a schematic diagram of the morphology corresponding to FIG. 10A, the dark gray stripes in FIG. 10B represent TIPS-TAP crystals, and the light gray stripes represent diF-TES-ADT crystals. It can be clearly observed the uniform morphology in the bilayer organic single crystals, and the overall morphology including the crystal thickness is well controlled. The FIG. 11A shows a larger range (at 20× magnification) observation of diF-TES-ADT and TIPS-TAP bilayer organic single-crystalline heterojunction composite films under an optical microscope. The FIG. 11B is the corresponding polarized optical microscopic image of FIG. 11A, it can be seen that laminating coupled growth can be realized in the organic single-crystalline heterojunction composite film for achieving highly efficient lamination ratio, moreover, the two-dimensional high coverage and large-area continuous growth are achieved at the same time. The uniform color in the optical microscopic image once again proves the well-regulated crystal thickness. In addition, the birefringence behavior exhibited in the heterojunction composite film displayed in the polarized optical microscopic image in FIG. 11B indicates its single-crystalline nature, thereby, the obtained bilayer heterojunction composite film is proved as an organic single-crystalline heterojunction composite film. The morphology and sophisticated structure of organic single-crystalline thin film in the optical microscopic image could be analyzed via using software that can analyze image pixels (such as Image J software, Matlab, Photoshop, Adobe Illustrator, etc., the present disclosure takes Image J software as an example). For example, the lamination area ratio between diF-TES-ADT organic single-crystalline thin film and TIPS-TAP organic single-crystalline thin film can be calculated in the FIG. 10, seven adjacent crystals in TIPS-TAP organic single-crystalline thin film (which has a relatively larger area in the two organic single-crystalline thin film) are randomly selected for the calculation, and the selected area is shown in FIGS. 10A-10B. A_{large}=1432.59 μm²+1384.30 μm²+1471.49 μm²+1561.36 μm²+1625.75 μm²+1191.15 μm²+1239.44 μm²=9906.0 8 μm², A_{large} is the total area of 7 TIPS-TAP crystals, Aₜₒₜₐₗ=(901.41 μm²+692.15 μm²+949.70 μm²+885.30 μm²+997.99 μm²+820.92 μm²+7 88.72 μm²)=6036.19 μm², Aₜₒₜₐₗ is the sum of the lamination area between the 7 selected TIPS-TAP crystals and the 7 selected diF-TES-ADT crystals in diF-TES-ADT single-crystalline thin film (which has a relatively smaller area in the two organic single-crystalline thin film). Thereby, R=Aₜₒₜₐₗ/A_{large}=55.8% could be calculated. The requirement that the lamination area ratio needs to be greater than or equal to 50% could be achieved, which means that the highly efficient lamination of the organic single-crystalline efficiently coupled unit could be realized. Selecting 7 adjacent TIPS-TAP crystals for calculating the vertical coverage ratio of the organic single-crystalline thin film, R_{V}=((87.73 μm+87.73 μm+87.73 μm+87.73 μm+87.73 μm+87.73 μm+87.73 μm)/7)/87.73 μm=100%, therefore, it can be considered that the high/full vertical coverage ratio is achieved in the direction V. The quite high horizontal coverage ratio is also obtained in the direction H, R_{H}=(16.51 μm+15.96 μm+16.70 μm+16.70 μm+18.72 μm+13.39 μm+13.03 μm)/117.25 μm=94.68%, thus, the two-dimensional high coverage is ensured, moreover, it could be considered as realizing almost full coverage, which provides a large-area channel for charge carrier transport. For the degree of laminated orientation calculation, firstly, select 7 crystals in the diF-TES-ADT organic single-crystalline thin film and calculate the average orientation angle Ā_{T} of the 7 crystals (the reference direction is the same as the direction V), Ā_{T}=((−0.74°)+(−1.19°)+0.55°+1.70°+0.99°+0.45°+1.61°)/7=0.48°, then select 7 crystals in the TIPS-TAP organic single-crystalline thin film and calculate the average orientation angle Ā_{B} of the 7 crystals (the reference direction is the same as the direction V), Ā_{B}=(0.45°±0.82°±1.79°±2.87°±1.25°±1.79°+1.17°)/7=1.45°, the laminated orientation angle could be obtained, Ā=(Ā_{T}−Ā_{B})=−0.97°, finally, the degree of laminated orientation could be calculated, F_{L}=0.5*(3*cos²Ā−1)=0.999, the F_{L} is very close to 1, which indicates that the almost completely parallel orientation is achieved. Therefore, the lamination coupling (that is, the well-aligned/uniformly orientated lamination) in the bilayer organic single-crystalline heterojunction composite film is verified, and the realization of synergistic growth for bilayer organic single crystals provides convenience for the subsequent preparation of devices and exhibition of high-performance electronic/optoelectronic behaviors. The diF-TES-ADT single-crystalline thin film is grown on top of the TIPS-TAP single-crystalline thin film, and the two organic single-crystalline thin films are combined by laminating (as shown in FIG. 3B). A single-crystalline heterojunction with a clear bilayer structure is formed, as shown in the scanning electron microscopic image shown in FIG. 12, the diF-TES-ADT single crystals are selectively grown on the upper surface of the TIPS-TAP single crystals, and the obtained bilayer single-crystalline heterojunction composite film is completely laminated, which is beneficial for the formation of a high-quality heterojunction interface and satisfying the requirements of an organic single-crystalline efficiently coupled unit. The FIG. 13 shows the transfer curve of hole and electron transport of a typical ambipolar organic field-effect transistor (V_{DS}=−120V, _{VG}=−120V) based on the organic single-crystalline heterojunction composite film prepared in Example 1, respectively. After calculation, both the hole and electron mobility in the saturation region exceeds 0.1 cm²V⁻¹s⁻¹, as shown in Table 3, a good ambipolar performance of charge carrier transport is achieved.

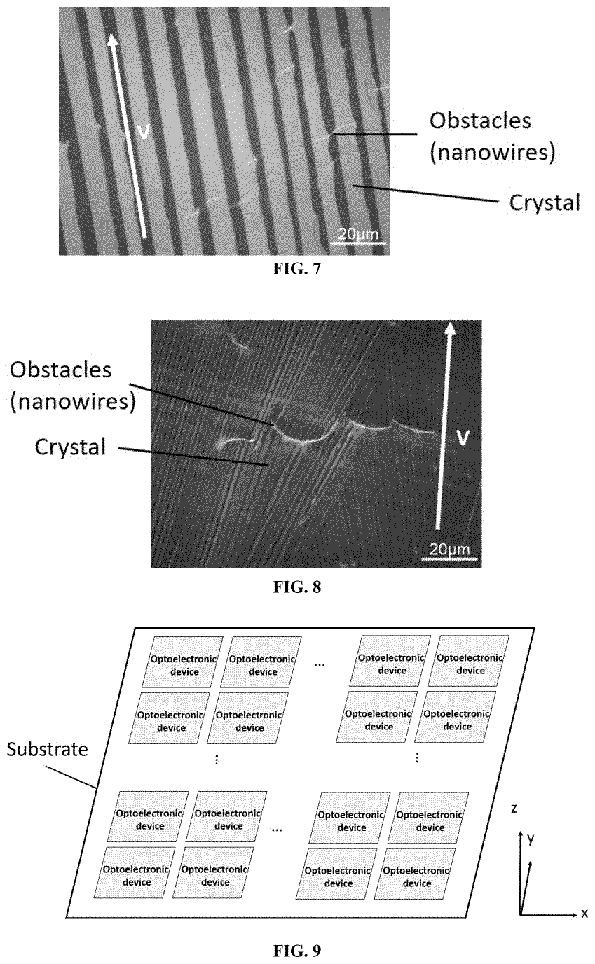

In the process of laminating coupled growth, due to the different structures of the two organic molecules (for example, diF-TES-ADT comprises S atoms in the core and F atoms in the side chain, thus there are F-F and F-S interactions existed between the molecules), the different interaction between solutes and the substrate modification layer, the different interaction between solutes and the solvents, and the different crystallization rate of the two organic molecules (the different crystallization rate referring to the crystallization rate is not exactly the same) in the solution under the shearing force, therefore, there is the possibility of realizing horizontal phase separation and/or vertical phase separation at different interfaces, as the laminating coupled growth mode of the bilayer organic single-crystalline thin film shown in Table 1. For example, FIG. 7 and FIG. 8, the detection method for vertical phase separation is to observe whether the morphology changes when the crystal crossing the obstacles (nanowires). In FIG. 7, 7 crystals whose crystal growth direction crosses the silver nanowire obstacles are selected, through analysis by ImageJ software, we can observe the angles between the silver nanowire and the vertical crystal growth direction where the crystal meets the silver nanowire are both less than 45° (specifically, |Aₒ| is 27.00°, 29.06°, 13.13°, 18.44°, 3.37°, 10.62°,23.20°), thus the requirements of obstacles are satisfied. The average thickness of silver nanowire h̅ₒ is about 40±5 nm, and the average thickness of the crystal h̅ₒ is about 25±3 nm, |h̅ₒ−h̅|<20 nm, when the morphology of 7 crystals is basically unchanged before and after crossing the silver nanowires, the growth mode can be determined as having an air-liquid interface.

The morphologies of the organic single-crystalline heterojunction composite films obtained in Examples 2-17 are similar to those in FIG. 10 and FIG. 11, the thickness, width, and gap of the crystals are only slightly changed, thus the detailed description will be omitted here. The organic field-effect transistors obtained in Examples 2-6 and Examples 9-10 all exhibited obvious ambipolar transport performance, and the obtained hole and electron mobility are shown in Table 4, respectively, which can be applied to electroluminescent devices and complementary integrated circuits.

In order to illustrate that the organic single-crystalline heterojunction composite film provided by the present disclosure has a highly ordered heterojunction interface, Comparative Example 1 and Comparative Example 2 adopt two different types of organic semiconductor small molecules (p-type perylene and n-type TIPS-TAP), the organic single-crystalline & polycrystalline heterojunction was prepared by combining the solution and evaporation method. The polycrystalline thin film can be determined through the characterization of the optical microscope. Through the characterization, an organic single-crystalline & polycrystalline heterojunction is obtained in Comparative Example 1, and organic polycrystalline & polycrystalline heterojunction c is obtained Comparative Example 2. The performance of organic field-effect transistors prepared based on the two heterojunctions aforementioned (which are not single-crystalline state) is shown in Table 4. It can be observed that the hole and electron mobility has dropped by nearly an order of magnitude compared with heterojunction composite film containing two single-crystalline thin films (for example, organic single-crystalline heterojunction composite film in Example 1). In Comparative Example 1, the hole mobility is 0.007 cm²V⁻¹s⁻¹, and the electron mobility is 0.04 cm²V⁻¹s⁻¹, the hole and electron mobility in Comparative Example 2 are 0.008 cm²V⁻¹s⁻¹ and 0.02 cm²V⁻¹s⁻¹, respectively. Both examples well illustrated that the order of the heterojunction interface formed by organic single-crystalline & polycrystalline or organic polycrystalline & polycrystalline is greatly reduced, which affects the transport performance of the two types of charge carriers.

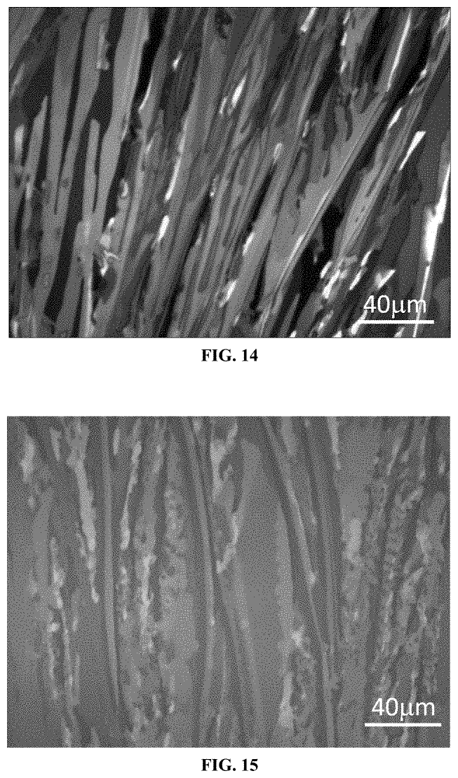

In the mixed solution, the control of the growth rate and/or the difference in growth interface between different solutes is needed to obtain horizontal phase separation and/or vertical phase separation, the mutual interference of different solutes during nucleation crystal growth should be avoided, or else the morphology of the organic single-crystalline heterojunction composite film will be affected. In order to illustrate the importance of the control aforementioned, two solutes having the same growth interfaces (the air-liquid interface) and similar growth rates are used for comparison in Comparative Example 3. The morphology of the obtained heterojunction composite film is shown in FIG. 14, the quite uneven color/gray-scale of the crystals could be observed in the polarized optical microscopic image, indicating that the obtained organic film is polycrystalline, and it is even impossible to distinguish the respective morphologies of different types of organic films. If the horizontal phase separation or vertical phase separation is not existed when the different solutes are mixed in the same solution, serious interference to the nucleation growth of crystals will be caused, thus, it is impossible to obtain a single-crystalline thin film, furthermore, it is impossible to obtain an organic single-crystalline efficiently coupled unit with lamination coupling properties, which is harmful to the subsequent preparation of optoelectronic devices.

In order to illustrate that the solutes need to be fully dissolved in the mixed solution, Comparative Example 4 choose 1-butanol as the solvent, which has a lower solubility for the selected solute molecules. Since the solubility of the two solutes in 1-butanol is not high enough, the solubility S is <0.05 wt % under stable conditions, ultimately, almost no corresponding organic single-crystalline heterojunction composite film is obtained on the substrate. This is because solvent evaporates very quickly, and solutes with insufficient solubility are easier to precipitate out, as a result, under the applied shearing force, the supply of raw materials in the solution storage space has been exhausted before the crystal grows, only some solid residues can be obtained on the substrate in the end.

In order to illustrate that the growth conditions of the organic single-crystalline heterojunction composite film preparation method provided by the present disclosure need to be strictly controlled, Comparative Examples 5-7 used the same materials, the same substrate modification layer, the same solvent and the same growth temperature as in Example 1. However, due to the growth conditions are not precisely controlled, such as the standing time is too long or too short, the distance between the shearing tool and the substrate is too large, the shearing speed is too fast or too slow, the ambient temperature is too high, or the ambient humidity is too high, the mismatch will be caused between the solute deposition rate, the solvent evaporation rate and the meniscus movement speed owing to the factors aforementioned, therefore, the stable growth environment cannot be provided for obtaining organic single-crystalline heterojunction composite film with ideal morphology. The morphology of the organic heterojunction composite film obtained in Comparative Example 7 is shown in the optical microscopic image of FIG. 15 (the morphologies of Comparative Examples 5 and 6 are similar to those of Comparative Example 7), a lot of randomly oriented, curved or discontinuous crystals are displayed (the degree of laminated orientation is 0.389), the coverage ratio (including horizontal and vertical direction) of the crystal is low (R_{V}=76.41%, R_{H}=54.90%), similarly, the lamination area ratio between the two layer of crystals is also quite low (R=23.55%). Attributed to the non-regular crystal morphology, the double-layer crystals obtained without controlling the growth conditions is difficult to be applied for preparing optoelectronic devices. Moreover, due to the uncertainty of the morphology, the obtained electronic/optoelectronic behaviors are unable to be corrected, thus the real performance cannot be reflected. The only device prepared in Comparative Example 7 is also showing a low performance (the p-type mobility is 0.0003 cm²V⁻¹s⁻¹, and the n-type mobility cannot be detected).

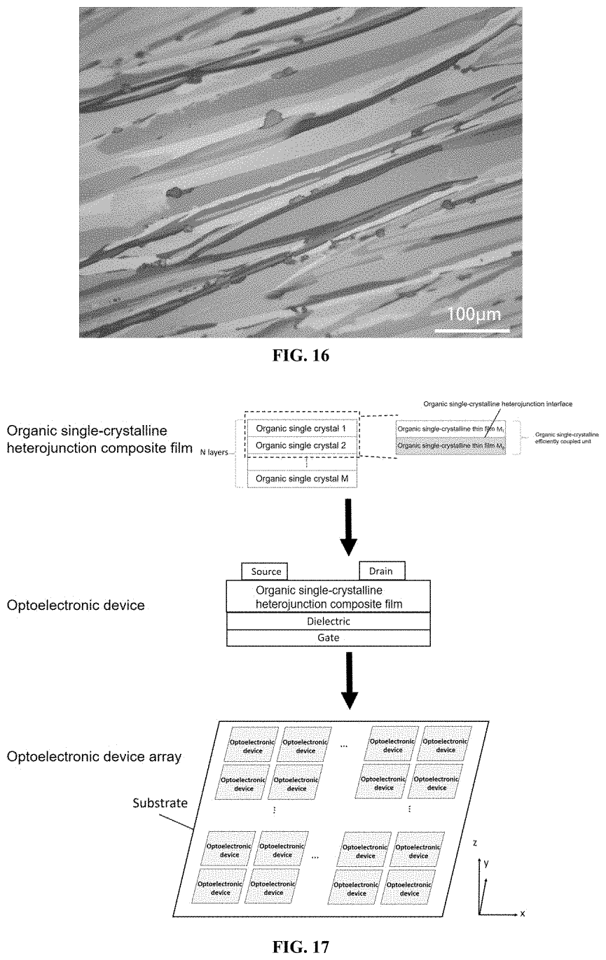

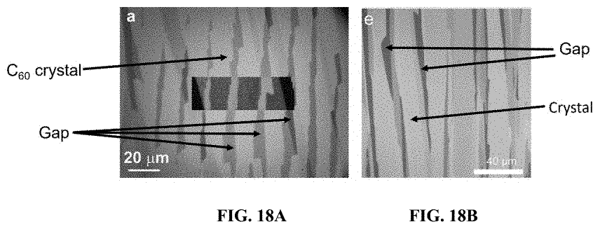

In order to illustrate the advantages of the preparation method provided by the present disclosure in obtaining the well-control over the morphology of organic single-crystalline heterojunction composite films, Comparative Example 8 uses the mechanical transfer method to prepare the organic single-crystalline heterojunction composite film, the diF-TES-ADT film prepared on the PDMS is transferred onto the pre-formed TIPS-TAP film to fabricated the heterojunction composite film through the physical electrostatic adsorption. First of all, the difficulties in positioning caused by the manual operation leads to myriad challenges in realizing large-scale transferring, so the ratio of successful lamination of the heterojunction composite film is very low. Additionally, since the thickness of the diF-TES-ADT organic single-crystalline thin film is only about 20 nm, many cracks appear on the crystal surface due to stress during the mechanical transferring process, the quality of the crystal is severely damaged, and it is hard to control the degree of orientation of the lamination between the two layers of films, leading to the inconsistent laminated orientation between the final double-layer films. As a result, the lamination area between the double-layer films is reduced, and the ambipolar transport performance is seriously affected. The performance obtained is shown in Table 4, the device does not show p-type performance, only the electron mobility of 0.13 cm²V⁻¹s⁻¹ is obtained. Comparative Example 9 used a two-step orthogonal solvent method to grow two layers of organic single crystals. Since the already grown TIPS-TAP organic single-crystalline thin film has become the roadblock for the growth of the second layer organic single-crystalline thin film (diF-TES-ADT), leading to the disturbance to the orientation of diF-TES-ADT during growth. The crystals are prone to display bifurcation or bending morphology, moreover, part of the crystals will stop growing due to the hindrance of the growth front, result in the non-uniform morphology of the organic heterojunction film ultimately. On the other hand, when the second layer of diF-TES-ADT organic single-crystalline thin film is grown, the diF-TES-ADT solution is spread on the already grown TIPS-TAP organic single-crystalline thin film, causing damage to the crystal surface of the TIPS-TAP thin film. As a result, the quality of the organic heterojunction interface is degraded. As the performance of the organic field-effect transistor shown in Table 4, the greatly reduced mobilities (the hole mobility is 0.10 cm²V⁻¹s⁻¹, and the electron mobility is 0.003 cm²V⁻¹s⁻¹) prove that the crystal surface of the TIPS-TAP single-crystalline thin film has been damaged. Comparative Example 10 used the DPC method reported in H. Li et al., Advanced Materials, 24, 2588 (2012) to prepare an organic single-crystalline heterojunction composite film with a mixed solution, the same materials as in Example 1 are adopted. As shown in the optical microscopic image of FIG. 16, due to the lack of directional shearing, a suitable morphology cannot be obtained in the organic heterojunction composite film, and two types of organic crystals can barely be distinguished, which causing barriers for subsequent realization of electronic/optoelectronic behaviors. Because of the difficulty in distinguishing the morphology of heterojunction film, it is possible that the performance of one type of organic semiconductor molecules has not been reflected, therefore the ambipolar transport cannot be realized in the organic heterojunction. The performance of the obtained device is shown in Table 4, only the hole mobility of 0.06 cm²V⁻¹s⁻¹ is exhibited while the electron transport performance is not obtained.

In summary, through Comparative Examples 1-10, it can be explained that only the method for preparing the organic single-crystalline heterojunction composite film provided by the present disclosure could be used to realize the laminating coupled growth of the organic single-crystalline efficiently coupled unit. Thereby, an organic single-crystalline heterojunction composite film is obtained with high quality heterojunction interface, highly efficient lamination, and at least one layer of organic single-crystalline thin film to achieve an ideal morphology with two-dimensional high coverage.

Through Examples 1-17 and Comparative Examples 1-10, it can be illustrated that the following three conditions must be met in order to achieve the preparation of organic heterojunction composite films (possessing ideal material form, morphology and structure) and related optoelectronic devices: 1) In the organic heterojunction composite film, each component should be guaranteed in the single-crystalline form, and a high-quality heterojunction interface must be realized; 2) the two or more layers of organic single-crystalline thin films are grown through laminating coupled growth to achieve highly efficient lamination, that is, an organic single-crystalline heterojunction composite film with laminated structure which comprises a large lamination area ratio; 3) at least one organic single-crystalline thin film in the organic single-crystalline heterojunction composite film can achieve two-dimensional high coverage. If the first two conditions are met, a high-quality organic single-crystalline heterojunction composite film can be obtained, and the morphology and device performance have been greatly improved compared with the existing level. For an organic single-crystalline heterojunction composite film with an ideal morphology, the three prerequisites aforementioned need to synergistically work together to achieve the purpose of the present disclosure.

TABLE 1
Formulations and process parameters A of Example 1-17 and Comparative
Example 3-7 (substrate, modification layer, solutes and their respective
ratio, solvent, shearing temperature and shearing velocity)

| | | modification | | | shearing | shearing | |
|---|---|---|---|---|---|---|---|
| No. | substrate | layer | solutes and their respective ratio | solvent | temperature | velocity | |
| Example 1 | SiO₂ | c-PS | diF-TES-ADT:TIPS-TAP = 1:1 | Mesitylene | 60° C. | 400 ± 5 | μm/s |
| Example 2 | SiO₂ | c-PS | diF-TES-ADT:TIPS-TAP = 1:1 | Mesitylene | 80° C. | 800 ± 5 | μm/s |
| Example 3 | SiO₂ | c-PS | diF-TES-ADT:TIPS-TAP = 1:1 | Mesitylene | 40° C. | 200 ± 5 | μm/s |
| Example 4 | SiO₂ | c-PS | diF-TES-ADT:TIPS-TAP = 2:1 | Mesitylene | 60° C. | 400 ± 5 | μm/s |
| Example 5 | SiO₂ | c-PS | diF-TES-ADT:TIPS-TAP = 1:2 | Mesitylene | 60° C. | 400 ± 5 | μm/s |
| Example 6 | SiO₂ | PMMA | diF-TES-ADT:TIPS-TAP = 1:1 | N-octane | 40° C. | 50 ± 1 | μm/s |
| Example 7 | PEN | c-PMMA | TIPS-PEN:C₈-BTBT = 1:1 | Toluene: | 30° C. | 10 ± 1 | μm/s |
| | | | | CHCl₃ = 1:1 | | | |
| Example 8 | SiO₂ | c-PMMA | TIPS-PEN:C₈-BTBT = 1:1 | CHCl₃ | 0° C. | 10 ± 1 | μm/s |
| Example 9 | SiO₂ | OTS | Perylene:TIPS-TAP = 1:1 | Toluene | 100° C. | 2000 ± 20 | μm/s |
| Example 10 | SiO₂ | PMMA & | Perylene:TIPS-TAP = 1:2 | Toluene: | 50° C. | 600 ± 5 | μm/s |
| | | P(VDF- | | Heptane = 1:1 | | | |
| | | TrFE- | | | | | |
| | | CFE) | | | | | |
| Example 11 | SiO₂ | PVA | TIPS-PEN:9,10-DPA = 1:1 | Toluene | 60° C. | 400 ± 10 | μm/s |
| Example 12 | SiO₂ | c-PVP | TIPS-PEN:9,10-DPA = 1:1 | Dodecane | 80° C. | 1000 ± 5 | μm/s |
| Example 13 | AlOₓ | ODPA | Tetracene:TIPS-TAP = 1:1 | M-xylene | 60° C. | 200 ± 1 | μm/s |
| Example 14 | SiO₂ | PI | Tetracene:TIPS-TAP = 1:1 | M-xylene | 80° C. | 800 ± 10 | μm/s |
| Example 15 | SiO₂ | PI | TIPS-TAP:dp-dtt = 1:1 | P-xylene | 80° C. | 800 ± 5 | μm/s |
| Example 16 | SiO₂ | PI | Rubrene:C₆₀ = 1:1 | 1-chloro- | 200° C. | 20 ± 1 | μm/s |
| | | | | naphthalene | | | |
| Example 17 | SiO₂ | PI | Rubrene:C₆₀ = 1:1 | Chlorobenzene | 60° C. | 400 ± 5 | μm/s |
| Comparative | SiO₂ | c-PS | diF-TES-ADT:TIPS-PEN = 1:1 | Mesitylene | 60° C. | 400 ± 5 | μm/s |
| Example 3 | | | | | | | |
| Comparative | SiO₂ | c-PS | diF-TES-ADT:TIPS-TAP = 1:1 | 1-butanol | 60° C. | 400 ± 5 | μm/s |
| Example 4 | | | | | | | |
| Comparative | SiO₂ | c-PS | diF-TES-ADT:TIPS-TAP = 1:1 | Mesitylene | 60° C. | 5 ± 1 | μm/s |
| Example 5 | | | | | | | |
| Comparative | SiO₂ | c-PS | diF-TES-ADT:TIPS-TAP = 1:1 | Mesitylene | 60° C. | 10000 ± 20 | μm/s |
| Example 6 | | | | | | | |
| Comparative | SiO₂ | c-PS | diF-TES-ADT:TIPS-TAP = 1:1 | Mesitylene | 60° C. | 200 ± 5 | μm/s |
| Example 7 | | | | | | | |

**The actual process parameters (including the shearing temperature and shearing velocity) are allowed to have a deviation of ±2% from the parameters listed in the table.

TABLE 2
Formulations and process parameters B of Example 1-17 and Comparative
Example 3-7 (standing time, ambient temperature, ambient humidity, gap distance, the
solubility of solute (S) and laminating coupled growth fashion between two layers of
organic single-crystalline thin films)

| | | | | | | | solubility | laminating |
|---|---|---|---|---|---|---|---|---|
| | standing | | ambient | ambient | gap | | of solute | coupled growth |
| No. | time | | temperature | humidity | distance | | (S) | fashion |
| Example 1 | 5 | s | 20 ± 1° C. | 50 ± 3% | 200 ± 5 | μm | S > 0.5 wt % | Horizontal and |
| | | | | | | | | Vertical phase |
| | | | | | | | | separation |
| Example 2 | 10 | s | 20 ± 1° C. | 50 ± 3% | 200 ± 5 | μm | S > 0.5 wt % | Horizontal and |
| | | | | | | | | Vertical phase |
| | | | | | | | | separation |
| Example 3 | 5 | s | 20 ± 1° C. | 50 ± 3% | 200 ± 5 | μm | S > 0.5 wt % | Horizontal and |
| | | | | | | | | Vertical phase |
| | | | | | | | | separation |
| Example 4 | 5 | s | 20 ± 1° C. | 50 ± 3% | 200 ± 5 | μm | S > 0.5 wt % | Horizontal and |
| | | | | | | | | Vertical phase |
| | | | | | | | | separation |
| Example 5 | 5 | s | 20 ± 1° C. | 50 ± 3% | 150 ± 5 | μm | S > 0.5 wt % | Horizontal and |
| | | | | | | | | Vertical phase |
| | | | | | | | | separation |
| Example 6 | 5 | s | 20 ± 1° C. | 40 ± 2% | 150 ± 5 | μm | S > 0.05 wt % | Horizontal and |
| | | | | | | | | Vertical phase |
| | | | | | | | | separation |
| Example 7 | 10 | s | 20 ± 1° C. | 40 ± 2% | 200 ± 5 | μm | S > 0.5 wt % | Horizontal phase |
| | | | | | | | | separation |
| Example 8 | 10 | s | 20 ± 1° C. | 40 ± 2% | 200 ± 5 | μm | S > 0.5 wt % | Horizontal phase |
| | | | | | | | | separation |
| Example 9 | 15 | s | 25 ± 1° C. | 50 ± 3% | 150 ± 5 | μm | S > 0.5 wt % | Horizontal phase |
| | | | | | | | | separation |
| Example 10 | 2 | s | 25 ± 1° C. | 50 ± 3% | 150 ± 5 | μm | S > 0.5 wt % | Horizontal phase |
| | | | | | | | | separation |
| Example 11 | 15 | s | 25 ± 1° C. | 50 ± 3% | 300 ± 5 | μm | S > 0.5 wt % | Horizontal and |
| | | | | | | | | Vertical phase |
| | | | | | | | | separation |
| Example 12 | 15 | s | 25 ± 1° C. | 50 ± 3% | 300 ± 5 | μm | S > 0.5 wt % | Horizontal and |
| | | | | | | | | Vertical phase |
| | | | | | | | | separation |
| Example 13 | 15 | s | 25 ± 1° C. | 30 ± 1% | 300 ± 5 | μm | S > 0.5 wt % | Horizontal phase |
| | | | | | | | | separation |
| Example 14 | 10 | s | 25 ± 1° C. | 30 ± 2% | 300 ± 5 | μm | S > 0.5 wt % | Horizontal phase |
| | | | | | | | | separation |
| Example 15 | 10 | s | 25 ± 1° C. | 30 ± 2% | 200 ± 5 | μm | S > 0.5 wt % | Horizontal phase |
| | | | | | | | | separation |
| Example 16 | 5 | s | 25 ± 1° C. | 30 ± 2% | 200 ± 5 | μm | S > 0.05 wt % | Vertical phase |
| | | | | | | | | separation |
| Example 17 | 5 | s | 20 ± 1° C. | 50 ± 3% | 200 ± 5 | μm | S > 0.05 wt % | Vertical phase |
| | | | | | | | | separation |
| Comparative | 10 | s | 25 ± 1° C. | 50 ± 2% | 200 ± 5 | μm | S > 0.5 wt % | N/A |
| Example 3 | | | | | | | | |
| Comparative | 10 | s | 25 ± 1° C. | 50 ± 2% | 200 ± 5 | μm | S > 0.5 wt % | N/A |
| Example 4 | | | | | | | | |
| Comparative | 60 | s | 30 ± 3° C. | 50 ± 5% | 50 ± 1 | μm | S > 0.5 wt % | N/A |
| Example 5 | | | | | | | | |
| Comparative | 0 | s | 40 ± 3° C. | 70 ± 3% | 200 ± 5 | μm | S > 0.5 wt % | N/A |
| Example 6 | | | | | | | | |
| Comparative | 60 | s | 25 ± 1° C. | 70 ± 5% | 800 ± 100 | μm | S > 0.5 wt % | N/A |
| Example 7 | | | | | | | | |

** The actual process parameters (including standing time, ambient temperature, ambient humidity, gap distance, and solubility of solute (S)) are allowed to have a deviation of ±2% from the parameters listed in the table.

TABLE 3
Morphology parameters of the organic single-
crystalline heterojunction composite film of
Examples 1-17 and Comparative Examples 5-7

| | | degree of | vertical | horizontal |
|---|---|---|---|---|
| | lamination | laminated | coverage | coverage |
| | area | orientation | ratio of | ratio of |
| No. | ratio R | F_{L} | M_{L} (R_{V}) | M_{L} (R_{H}) |
| Example 1 | 55.80% | 0.999 | 100% | 94.68% |
| Example 2 | 51.37% | 0.974 | 100% | 90.37% |
| Example 3 | 53.29% | 0.989 | 100% | 86.42% |
| Example 4 | 65.01% | 1 | 100% | 90.03% |
| Example 5 | 100% | 0.942 | 100% | 89.67% |
| Example 6 | 55.03% | 0.873 | 98.76% | 85.48% |
| Example 7 | 80.04% | 0.725 | 89.37% | 82.45% |
| Example 8 | 91.22% | 0.664 | 82.17% | 71.31% |
| Example 9 | 50.97% | 0.631 | 84.62% | 75.99% |
| Example 10 | 57.20% | 0.706 | 92.07% | 73.65% |
| Example 11 | 73.67% | 0.980 | 95.33% | 80.12% |
| Example 12 | 65.05% | 0.965 | 92.18% | 84.49% |
| Example 13 | 61.64% | 0.878 | 99.76% | 87.23% |
| Example 14 | 73.54% | 0.922 | 100% | 89.56% |
| Example 15 | 82.57% | 0.839 | 83.95% | 76.38% |
| Example 16 | 52.95% | 0.653 | 84.08% | 77.97% |
| Example 17 | 50.76% | 0.741 | 89.32% | 81.90% |
| Comparative | 25.83% | 0.395 | 96.37% | 67.49% |
| Example 5 | | | | |
| Comparative | 43.20% | 0.237 | 89.12% | 42.73% |
| Example 6 | | | | |
| Comparative | 23.55% | 0.389 | 76.41% | 54.90% |
| Example 7 | | | | |

**Actually obtained crystal morphology parameters (including lamination area ratio R, degree of laminated orientation F_{L}, vertical coverage ratio of M_{L} (R_{V}) and horizontal coverage ratio of M_{L} (R_{H})) are allowed ±3% deviation from the tested parameters listed in the table.

TABLE 4
Performance statistics of saturation region mobilities of the
organic single-crystalline field-effect transistors at V_{DS} = −120 V,
V_{G} = −120 V obtained in Examples 1-6, Example 9-10 and
Comparative Examples 1-2, Comparative Examples 4,
Comparative Examples 7-10.

| | Hole mobility | | Electron mobility | |
|---|---|---|---|---|
| Example 1 | 0.13 | cm²V⁻¹s⁻¹ | 0.20 | cm²V⁻¹s⁻¹ |
| Example 2 | 0.11 | cm²V⁻¹s⁻¹ | 0.16 | cm²V⁻¹s⁻¹ |
| Example 3 | 0.08 | cm²V⁻¹s⁻¹ | 0.18 | cm²V⁻¹s⁻¹ |
| Example 4 | 0.12 | cm²V⁻¹s⁻¹ | 0.13 | cm²V⁻¹s⁻¹ |
| Example 5 | 0.14 | cm²V⁻¹s⁻¹ | 0.16 | cm²V⁻¹s⁻¹ |
| Example 6 | 0.17 | cm²V⁻¹s⁻¹ | 0.12 | cm²V⁻¹s⁻¹ |
| Example 9 | 0.09 | cm²V⁻¹s⁻¹ | 0.25 | cm²V⁻¹s⁻¹ |
| Example 10 | 0.05 | cm²V⁻¹s⁻¹ | 0.37 | cm²V⁻¹s⁻¹ |
| Comparative Example 1 | 0.007 | cm²V⁻¹s⁻¹ | 0.04 | cm²V⁻¹s⁻¹ |
| Comparative Example 2 | 0.008 | cm²V⁻¹s⁻¹ | 0.02 | cm²V⁻¹s⁻¹ |
| Comparative Example 4 | 0.05 | cm²V⁻¹s⁻¹ | 0.08 | cm²V⁻¹s⁻¹ |
| Comparative Example 7 | 0.0003 | cm²V⁻¹s⁻¹ | N/A | |
| Comparative Example 8 | N/A | | 0.13 | cm²V⁻¹s⁻¹ |
| Comparative Example 9 | 0.10 | cm²V⁻¹s⁻¹ | 0.003 | cm²V⁻¹s⁻¹ |

| | | | |
|---|---|---|---|
| Comparative Example 10 | 0.06 | cm²V⁻¹s⁻¹ | N/A |

What is claimed is:

1. An organic single-crystalline heterojunction composite film, wherein the organic single-crystalline heterojunction composite film comprises M organic materials, and M is a positive integer greater than or equal to 2;
the organic single-crystalline heterojunction composite film comprises a laminated structure, wherein the laminated structure refers to the organic single-crystalline heterojunction composite film is composed of N layers of organic single-crystalline thin films stacked in sequence, and N is a positive integer greater than or equal to 2;
the organic single-crystalline thin film is composed of the organic single crystal array;
the organic single-crystalline heterojunction composite film comprises at least one organic single-crystalline efficiently coupled unit;
the organic single-crystalline efficiently coupled unit is composed of an organic single-crystalline thin film M_{T} and an organic single-crystalline thin film M_{B}, and the organic single-crystalline efficiently coupled unit has highly efficient lamination;
M_{T} and M_{B} are laminated together; materials constituting M_{T} and M_{B} are different;
the highly efficient lamination of the organic single-crystalline efficiently coupled unit refers that a lamination area ratio R is ≥50%;
the lamination area ratio R=Aₜₒₜₐₗ/A_{large}, wherein Aₜₒₜₐₗ refers to a lamination area between the two organic single-crystalline thin films which constitute the organic single-crystalline efficiently coupled unit, and A_{large} refers to an area of the larger one in the two thin films.

2. The organic single-crystalline heterojunction composite film of claim 1,
wherein a detection method of the lamination area ratio R comprises randomly selecting m adjacent crystals in the organic single-crystalline film M_{L} in the organic single-crystalline efficiently coupled unit; wherein M_{L} is the larger one in the two layers, R=Aₜₒₜₐₗ/A_{large}, A_{large} is the total area of the m crystals, A_{large}−A_{large1}+A_{large2}+ . . . +A_{largem}, where A_{large1}, A_{large2}, . . . A_{largem} represent the area of the 1, 2, . . . , m crystal, respectively; A_{large} is the total lamination area of the m crystals, Aₜₒₜₐₗ=Aₜₒₜₐₗ₁+Aₜₒₜₐₗ₂+ . . . +Aₜₒₜₐₗₘ, where Aₜₒₜₐₗ₁, Aₜₒₜₐₗ₂, Aₜₒₜₐₗₘ represent the lamination area of the 1, 2, . . . , m crystal, respectively; m is a positive integer greater than or equal to 7.

3. The organic single-crystalline heterojunction composite film of claim 1, wherein at least one organic single-crystalline thin film has a two-dimensional high coverage in the organic single-crystalline efficiently coupled unit; the two-dimensional high coverage refers that a vertical coverage R_{V} of the organic single-crystalline thin film is ≥80% in a direction V, and a lateral coverage R_{H} is >70% in a direction H; the direction V is the crystal growth direction while the direction H is vertical to the crystal growth direction.

4. The organic single-crystalline heterojunction composite film of claim 3, wherein R_{V}=(l₁+l₂+ . . . +lₙ)/nL, where l₁, l₂, . . . , lₙ represent the length of the 1, 2, . . . , n crystals in the direction V, respectively; and L is the length of the substrate in the direction V; R_{H}=(w₁+w₂+ . . . +wₙ)/W, where w₁, w₂, . . . , wₙ represent the width of the 1, 2, . . . , n crystals in the direction H, respectively; W is the width of a substrate in the direction H, and n is a positive integer greater than or equal to 7.

5. The organic single-crystalline heterojunction composite film of claim 1, wherein at least one organic single-crystalline thin film in the organic single-crystalline efficiently coupled unit is selected from organic semiconductor molecules;
other layers of organic single-crystalline thin films are selected from any one or more of organic semiconductor molecules, organic molecules with optoelectric properties, and organic molecules with ferroelectric properties;
other layers include one or more layers.

6. The organic single-crystalline heterojunction composite film of claim 5, wherein the organic semiconductor molecules are selected from any one or more of linear acenes and linear acene derivatives, linear heteroacenes and linear heteroacene derivatives, benzothiophene and benzothiophene derivatives, perylene and perylene derivatives, perylene diimides and perylene diimides derivatives, fullerene and fullerene derivatives, naphthalene diimides and naphthalene diimides derivatives.

7. The organic single-crystalline heterojunction composite film of claim 1, wherein the organic single-crystalline efficiently coupled unit has a lamination coupling;
the lamination coupling means that a lamination between the organic single-crystalline thin film M_{T} and the organic single-crystalline thin film M_{B} is well-aligned/uniformly orientated.

8. The organic single-crystalline heterojunction composite film of claim 7, wherein the well-aligned/uniformly orientated lamination means that a degree of laminated orientation F_{L}≥0.625.

9. The organic single-crystalline heterojunction composite film of claim 7, wherein a detection method of the laminated orientation degree F_{L} comprises: in the organic single-crystalline efficiently coupled unit, randomly selecting n crystals as samples in the M_{T} and M_{B} respectively, and n is a positive integer greater than or equal to 7;
taking the crystal growth direction as the reference direction, and taking the angle between the direction of the longest dimension c_{T} of the crystal C_{T} in the M_{T} and the reference direction as the orientation angle A_{T}, A_{T} is the average orientation angle of the n crystals in M_{T};
taking the angle between the direction of the longest dimension c_{B} of the crystal C_{B} in the M_{B} and the reference direction as the orientation angle A_{B}, Ā_{B} is the average orientation angle of the n crystals M_{B};
the laminated orientation degree F_{L}=0.5*(3*cos²Ā−1), where Ā=(Ā_{T}−Ā_{B}).

10. A preparation method of the organic single-crystalline efficiently coupled unit, wherein an organic single-crystalline efficiently coupled unit is obtained by a laminating coupled growth method;
the laminating coupled growth method refer to synergistic growth realized by M_{T} and M_{B} to acquire the organic single-crystalline efficiently coupled unit along a crystal growth direction;
the organic single-crystalline efficiently coupled unit is composed of M_{T} and M_{B} with highly efficient lamination;
M_{T} and M_{B} are laminated together, and the materials constituting the M_{T} and M_{B} are different;
the highly efficient lamination of the organic single-crystalline efficiently coupled unit refers that the lamination area ratio R is ≥50%;
R=Aₜₒₜₐₗ/A_{large}, Aₜₒₜₐₗ refers to the area between the two organic single-crystalline thin films in the organic single-crystalline efficiently coupled unit, and the A_{large} refers to the larger organic single-crystalline thin film in the two layers.

11. The preparation method of the organic single-crystalline efficiently coupled unit of claim 10, wherein the laminating coupled growth method refers to applying shearing to a mixed solution for obtaining an organic single-crystalline efficiently coupled unit;
the shearing refers to use a shearing tool to shear the mixed solution along a constant direction at a constant shearing speed and shearing temperature;
the mixed solution refers to a solution in which two or more solutes are simultaneously dissolved;
one of the solutes is selected from organic semiconductor molecules;
the two or more solutes have a common solvent;
the common solvent refers to a solvent in which the two or more solutes are simultaneously dissolved;
the common solvent includes one or more solvents;
a solubility (S) of the two or more solutes in a common solvent is ≥0.05 wt % (S≥0.05 wt %);
there is no mutual reaction and co-crystal formation between different solutes;
the two or more solutes realizes horizontal phase separation (unequal velocity phase separation) and/or vertical phase separation (different interface phase separation) during the crystal growth process;
the horizontal phase separation means that the crystal growth rate between different solutes is not completely equal;
the vertical phase separation means that the growth interface between different solutes is not completely the same;
the growth interface refers to the interface that initiates the nucleation and growth of crystals in the growing process;
the growth interface is selected from air-liquid interface and solid-liquid interface.

12. The preparation method of the organic single-crystalline efficiently coupled unit of claim 11, wherein type of the growth interface is determined by observing whether the morphology of the organic single-crystalline thin film show a significant change after crossing the obstacles;
the obstacles refer to the nanowires deposited on the substrate;
a detection method for determining the type of the growth interface is: randomly selecting 2p+1 crystals that cross the obstacles along the crystal growth direction, and p is a positive integer greater than or equal to 1, |Ao|≤45°, Ao represents the included angle between the obstacle which meet the selected crystal aforementioned and the direction perpendicular to the crystal growth direction;
the difference between the average thickness of the obstacles (h̅ₒ) and the average thickness of the crystals (h̅) is less than or equal to 20 nm, that is, |h̅ₒ−hₒ≤20 nm;
if there is no significant morphology change for p+1 crystals after crossing the obstacles, the growth interface is considered as the air-liquid interface;
if the morphology of p+1 crystals changes significantly after crossing the obstacles, the growth interface is the solid-liquid interface.

13. The preparation method of the organic single-crystalline efficiently coupled unit of claim 10, comprising:
(1) preparing the mixed solution with two or more solutes that is capable of achieving horizontal phase separation and/or vertical phase separation, dissolving two or more solutes with a common solvent to control the two or more solutes to realize laminating coupled growth in the mixed solution;
(2) regulating an ambient temperature and an ambient humidity of the growth environment to obtain a stable growth environment; during the crystal growth process, the deviation of the ambient temperature is ≤±2° C., and the deviation of the ambient humidity is ≤±3%;
(3) adjusting a distance between the shearing tool and the substrate to obtain a solution storage space, and the solution storage space is the space formed between the substrate and the lower surface of the shearing tool; the distance is 50 μm to 300 μm;
a deviation of the distance between the substrate and a lower surface of the shearing tool is ≤10 μm;
the lower surface of the shearing tool is basically parallel to the substrate;
(4) filling the mixed solution prepared in step (1) into the solution storage space in step (3), and keeping the solution still for 1 s to 30 s after filling;
(5) using a shearing tool to shear the mixed solution along a constant direction at a constant shearing speed and shearing temperature, in order to obtain the organic single-crystalline efficiently coupled unit;
each layer of the organic single-crystalline efficiently coupled unit is an organic single-crystalline thin film;
the constant shearing temperature refers to the deviation of the shearing temperature is ≤±1° C. during the shearing process;
the shearing temperature is 0° C. to 200° C.;
the shearing speed is 10 μm/s to 2000 μm/s.

14. The preparation method of the organic single-crystalline efficiently coupled unit according to claim 11, wherein the solute is any one or more selected from the group consisting of organic semiconductor molecules, photoelectric functional organic molecules, and ferroelectric functional organic molecules.

15. The preparation method of the organic single-crystalline efficiently coupled unit of claim 14, wherein the organic semiconductor is any one or more selected from the group consisting of linear acenes and linear acenes derivatives, linear heteroacenes and linear heteroacene derivatives, benzothiophene and benzothiophene derivatives, perylene and perylene derivatives, fullerene and fullerene derivatives, cyanide or halogen substituted compounds.

16. A preparation method of the organic single-crystalline heterojunction composite film, wherein the preparation method comprises steps in the preparation method of the organic single-crystalline efficiently coupled unit according to claim 11.

17. The preparation method of the organic single-crystalline heterojunction composite film of claim 16, comprising:
laminating single or multiple layers organic single-crystalline thin film fabricated by other methods onto the one or more fabricated organic single-crystalline efficiently coupled unit.

18. The preparation method of the organic single-crystalline heterojunction composite film of claim 17, wherein the other methods are any one or more selected from the group consisting of casting method, solution shearing method, spin coating method, printing method, vapor phase deposition, and mechanical transfer method

19. The preparation method of the organic single-crystalline heterojunction composite film of claim 16, comprising a post-treatment step; the post-treatment step refers to the post-treatment of the entire organic single-crystalline heterojunction composite films, and/or post-treatment of the organic single-crystalline efficiently coupled units, and/or post-treatment of each layer/multiple layers of organic single-crystalline thin films;
the post-treatment is selected from any one or more of annealing, vacuum treatment, solvent annealing treatment, or surface treatment;
the surface treatment is selected from any one or more of ultraviolet ozone treatment, plasma treatment, infrared light treatment, or laser etching.
